(19) United States
(12) Patent Application Publication
(10) Pub. No.: US 2011/0220871 A1
(43) Pub. Date: Sep. 15, 2011

(54) NITRIDE SEMICONDUCTOR LIGHT-EMITTING DEVICE AND SEMICONDUCTOR LIGHT-EMITTING DEVICE

(75) Inventors: Takeshi Kamikawa, Osaka (JP); Pablo Vaccaro, Osaka (JP); Shigetoshi Ito, Osaka (JP)

(73) Assignee: Sharp Kabushiki Kaisha, Osaka-shi, Osaka (JP)

(21) Appl. No.: 13/062,460

(22) PCT Filed: Sep. 3, 2009
(86) PCT No.: PCT/JP2009/065408

§ 371 Date: May 27, 2011

(30) Foreign Application Priority Data
Sep. 5, 2008 (JP) 2008-228741
Sep. 26, 2008 (JP) 2008-248530

(51) Int. Cl. H01L 33/06

(52) U.S. Cl. 257/13; 257/E33.012

(57) ABSTRACT

In a nitride semiconductor light-emitting device, a nitride semiconductor layer, a p-type nitride semiconductor layer and an active layer are successively stacked on an n-type nitride semiconductor layer. In a semiconductor light-emitting device, a first lower layer, a second lower layer, an active layer, and an upper layer having a thickness not greater than 40 nm are successively stacked on a substrate, and an interface of a second electrode for n-type in contact with the upper layer includes a metal of which a surface plasmon can be excited by light generated from the active layer.

This application is a national stage application under 35 USC 371 of International Application No. PCT/JP2009/065408, filed Sep. 3, 2009, which claims the priority of Japanese Patent Application Nos. 2008-228741, filed Sep. 5, 2008, and 2008-248530, filed Sep. 26, 2008, the contents of all of which prior applications are incorporated herein by reference.

### TECHNICAL FIELD

The present invention relates to a nitride semiconductor light-emitting device and particularly to a nitride semiconductor light-emitting device capable of achieving a lowered drive voltage by allowing good flow of a tunneling current.

In addition, the present invention relates to a semiconductor light-emitting device and particularly to a semiconductor light-emitting device having improved light emission efficiency by utilizing a surface plasmon effect.

### BACKGROUND ART

For example, Non-Patent Document 1 (IEEE JOURNAL OF SELECTED TOPICS IN QUANTUM ELECTRONICS, VOL. 8, NO. 4, JULY/AUGUST 2002, pp. 739-743) or the like discloses a nitride semiconductor light-emitting diode device using a tunnel junction, as one example of a nitride semiconductor light-emitting device including a nitride semiconductor.

FIG. 11 shows a schematic cross-sectional view of a conventional nitride semiconductor light-emitting diode device using a tunnel junction described in Non-Patent Document 1. This nitride semiconductor light-emitting diode device has such a structure that a GaN buffer layer 1102, an Si-doped n-type GaN layer 1103 (a layer thickness: 3 μm), an active layer 1104 having MQW constituted of a stack in which an InGaN layer (a layer thickness: 2 nm) and a GaN layer (a layer thickness: 8 nm) are alternately stacked six times, an Mg-doped p-type GaN layer 1105 (a layer thickness: 50 nm), an Mg-highly-doped p⁺ type GaN layer 1106 (a layer thickness: 10 nm), an Si-highly-doped n⁺ type GaN layer 1107 (a layer thickness: 10 nm), and an Si-doped n-type GaN layer 1108 (a layer thickness: 200 nm) are successively stacked on a sapphire substrate 1101, in which a first n electrode 1109 is formed on Si-doped n-type GaN layer 1103 and a second n electrode 1110 is formed on Si-doped n-type GaN layer 1108. Then, a tunnel junction is formed by a pn junction between Mg-highly-doped p⁺ type GaN layer 1106 and Si-highly-doped n⁺ type GaN layer 1107.

In such a nitride semiconductor light-emitting diode device using a tunnel junction, a current spreads in a plane of Si-doped n-type GaN layer 1108 and the current flows between Mg-doped p-type GaN layer 1105 and Si-doped n-type GaN layer 1108 by using the tunnel junction between Mg-highly-doped p⁺ type GaN layer 1106 and Si-highly-doped n⁺ type GaN layer 1107.

In addition, an attempt to improve light emission efficiency by utilizing surface plasmon has recently been made in a semiconductor light-emitting device.

A schematic cross-sectional view in FIG. 18 shows a nitride semiconductor light-emitting diode device utilizing surface plasmon disclosed in Patent Document 1 (Japanese Patent Laying-Open No. 2005-108982). In this nitride semiconductor light-emitting diode device, an n-type GaN layer 1802 (a layer thickness: approximately 5 μm), an n-type AlGaN cladding layer 1803 (a layer thickness: approximately 0.15 μm), a multiple quantum well active later 1804 including a plurality of GaN layers and a plurality of GaInN layers that are alternately stacked, a non-doped GaN protection layer 1805 (a layer thickness: approximately 10 nm), a p-type AlGaN cladding layer 1806 (a layer thickness: approximately 0.15 μm), and a p-type GaInN contact layer 1807 (a layer thickness: approximately 0.3 μm) are formed on a substrate 1801 in this order. A plurality of electrodes for p-type like islands having a three-layered structure including a Pd first electrode layer 1808 (a layer thickness: approximately 1 nm), an Ag second electrode layer 1809 (a layer thickness: approximately 2 nm), and an Au protection layer 1810 (a layer thickness: approximately 1 nm) are formed on p-type GaInN contact layer 1807. These electrodes for p-type like islands are periodically arranged two-dimensionally. Each electrode for p-type has an annular two-dimensional shape. Meanwhile, an electrode 1811 for n-type is formed on a lower surface of substrate 1801.

A surface plasmon frequency of Ag corresponds to a wavelength around a 430-nm band of a light wavelength and surface plasmon can be excited by light in a blue region slightly longer in wavelength than that. In the nitride semiconductor light-emitting diode device described in Patent Document 1, electrodes for p-type are arranged in a prescribed period and light in the blue region emitted from multiple quantum well active later 1804 is caused to pass through Ag second electrode layer 1809, so that surface plasmon is excited on a surface side of Ag second electrode layer 1809, to thereby obtain a surface plasmon effect.

It is noted that Pd first electrode layer 1808 included in the electrode for p-type is provided in order to establish good ohmic contact with p-type GaInN contact layer 1807, because Ag second electrode layer 1809 cannot establish good ohmic contact with p-type GaInN contact layer 1807. In addition, in order not to impede excitation of surface plasmon, Pd first electrode layer 1808 is formed on the surface side of Ag second electrode layer 1809, to an extremely small thickness.

In addition, Non-Patent Document 2 (Applied Physics Letters, Vol. 87, 071102 (2005)) discloses a technique for effectively achieving coupling between surface plasmon and light by arranging a semiconductor-Ag interface within near field of an active layer in a nitride semiconductor light-emitting diode device. Namely, this technique produces an effect by setting a thickness of a semiconductor layer between an active layer and an Ag layer to an extremely small thickness of 10 nm. Then, Non-Patent Document 2 reports that improvement in a spontaneous emission rate was actually observed in light emission from the active layer by optical pumping.

### PRIOR ART DOCUMENTS

### Patent Documents

Patent Document 1: Japanese Patent Laying-Open No. 2005-108982

### Non-Patent Documents

Non-Patent Document 1: Seong-Ran Jeon et al., “GaN-Based Light-Emitting Diodes Using Tunnel Junctions,” IEEE JOURNAL OF SELECTED TOPICS IN QUANTUM ELECTRONICS, VOL. 8, NO. 4, JULY/AUGUST 2002, pp. 739-743
Non-Patent Document 2: K. Okamoto et al., “Surface plasmon enhanced spontaneous emission rate of InGaN/GaN quantum wells probed by time-resolved photoluminescence spectroscopy,” Applied Physics Letters, Vol. 87, 071102 (2005).

### SUMMARY OF THE INVENTION

In the nitride semiconductor light-emitting diode device having the construction shown in FIG. 11, Si-doped n-type GaN layer 1108 can be doped with an n-type impurity to carrier density of approximately 3×10¹⁹ cm⁻³ and hence it can relatively easily be fabricated.

It is difficult, however, to attain high Mg doping concentration in Mg-highly-doped p⁺ type GaN layer 1106 forming a tunnel junction. As an amount of Mg doping increases, crystallinity of Mg-highly-doped p⁺ type GaN layer 1106 deteriorates and a surface is roughened, or to the contrary, resistance becomes higher.

Therefore, in the conventional nitride semiconductor light-emitting diode device shown in FIG. 11, Mg-highly-doped p⁺ type GaN layer 1106 having good crystallinity cannot be formed, and thus a depletion layer extends approximately to a little less than 40 nm at an interface between Mg-highly-doped p⁺ type GaN layer 1106 and Si-highly-doped n⁺ type GaN layer 1107. Then, a tunneling current does not flow well and resistance becomes higher.

In addition, in the nitride semiconductor light-emitting diode device disclosed in Patent Document 1, a light emission efficiency enhancement effect by the beneficial surface plasmon effect has not actually been achieved yet, because sufficient coupling between surface plasmon on the surface side of Ag second electrode layer 1809 and light emitted from multiple quantum well active later 1804 is actually difficult. Namely, in the nitride semiconductor light-emitting diode device disclosed in Patent Document 1, though extremely thin Pd first electrode layer 1808 is placed between Ag second electrode layer 1809 and p-type GaInN contact layer 1807, this Pd first electrode layer 1808 absorbs light from multiple quantum well active later 1804 and excitation of surface plasmon on the surface side of Ag second electrode layer 1809 is decreased.

Meanwhile, Non-Patent Document 2 discloses the technique to set a thickness of the semiconductor layer between the active layer and the Ag layer to 10 nm in order to arrange the Ag layer within the near field of the active layer. Even though such a technique disclosed in Non-Patent Document 2 is applied to the nitride semiconductor light-emitting diode device disclosed in Patent Document 1, however, light emission per se by multiple quantum well active later 1804 by current injection is difficult.

The first reason therefor is that good ohmic contact cannot be established if Ag second electrode layer 1809 and p-type GaInN contact layer 1807 are in direct contact with each other as in Non-Patent Document 2.

In addition, the second reason therefor is that, generally in a semiconductor such as a nitride semiconductor, it is difficult to obtain a p-type semiconductor having sufficiently high carrier concentration by doping with a p-type impurity, and if p-type GaInN contact layer 1807 has an extremely small thickness of approximately 10 nm as in Non-Patent Document 2, carrier concentration in p-type GaInN contact layer 1807 having such a small thickness cannot be high and holes for light emission cannot sufficiently be supplied to multiple quantum well active later 1804.

As described above, improvement in light emission efficiency of the semiconductor light-emitting device by utilizing the surface plasmon effect has not conventionally successfully been realized.

In view of the circumstances above, an object of the present invention is to provide a nitride semiconductor light-emitting device capable of achieving a lowered drive voltage by allowing good flow of a tunneling current.

In addition, in view of the circumstances above, an object of the present invention is to provide a semiconductor light-emitting device having improved light emission efficiency by making use of a surface plasmon effect.

The present invention is directed to a nitride semiconductor light-emitting device including: an n-type nitride semiconductor layer; a nitride semiconductor layer provided on the n-type nitride semiconductor layer; a p-type nitride semiconductor layer provided on the nitride semiconductor layer; and an active layer provided on the p-type nitride semiconductor layer.

In addition, the present invention is directed to a nitride semiconductor light-emitting device including: an n-type nitride semiconductor layer; a nitride semiconductor layer provided on the n-type nitride semiconductor layer and having a polar plane in at least a part thereof; a p-type nitride semiconductor layer provided on the nitride semiconductor layer; and an active layer provided on the p-type nitride semiconductor layer.

In addition, in the nitride semiconductor light-emitting device according to the present invention, the nitride semiconductor layer preferably contains aluminum.

In addition, in the nitride semiconductor light-emitting device according to the present invention, the nitride semiconductor layer is preferably AlₓGa₁₋ₓN (0<x≦1).

In addition, preferably, the nitride semiconductor light-emitting device according to the present invention includes a second n-type nitride semiconductor layer provided on the active layer, a first electrode in contact with the n-type nitride semiconductor layer is an anode electrode, and a second electrode in contact with the second n-type nitride semiconductor layer is a cathode electrode.

In addition, in the nitride semiconductor light-emitting device according to the present invention, the nitride semiconductor layer preferably has a thickness not smaller than 0.5 nm and not greater than 30 nm.

In addition, in the nitride semiconductor light-emitting device according to the present invention, preferably, the active layer has a well layer composed of a group III nitride semiconductor containing In, and an In composition ratio in the well layer is not lower than 0.15 and not higher than 0.4.

In addition, in the nitride semiconductor light-emitting device according to the present invention, preferably, the active layer has a well layer composed of a group III nitride semiconductor containing In, and an In composition ratio in the well layer is not lower than 0.2 and not higher than 0.4.

It is noted that the In composition ratio in the present invention means a ratio of the number of In atoms to the total number of atoms of an group III element forming the group III nitride semiconductor ((the number of In atoms)/(the total number of atoms of a group III element)).

In addition, the present invention is directed to a semiconductor light-emitting device including: a substrate; a first lower layer provided on the substrate and containing an n-type semiconductor; a second lower layer provided above the first lower layer and containing a p-type semiconductor; an active layer provided on the second lower layer; an upper layer provided on the active layer and containing an n-type semiconductor; a first electrode for n-type provided in contact with the substrate or the first lower layer; and a second electrode for n-type provided on the upper layer in contact therewith, the upper layer having a thickness not greater than 40 nm, and an interface of the second electrode for n-type in contact with the upper layer containing a metal of which surface plasmon can be excited by light generated from the active layer.

In addition, in the semiconductor light-emitting device according to the present invention, preferably, the metal of which surface plasmon can be excited by light generated from the active layer includes any of Ag, Au and Al as a main component. Moreover, in the nitride semiconductor light-emitting device according to the present invention, the first electrode for n-type may be an anode electrode and the second electrode for n-type may be a cathode electrode.

In addition, the semiconductor light-emitting device according to the present invention may be a nitride semiconductor light-emitting device. Moreover, preferably, the semiconductor light-emitting device according to the present invention further includes an intermediate layer between the first lower layer and the second lower layer, and the intermediate layer includes tensile strain attributed to difference in lattice constant between the first lower layer and the second lower layer. Further, in the semiconductor light-emitting device according to the present invention, the substrate may be an n-type conductive substrate and the first electrode for n-type is preferably provided in contact with the n-type conductive substrate.

According to the present invention, a nitride semiconductor light-emitting device capable of achieving a lowered drive voltage by allowing good flow of a tunneling current can be provided.

In addition, according to the present invention, a semiconductor light-emitting device having improved light emission efficiency by making use of a surface plasmon effect can be provided.

### BRIEF DESCRIPTION OF THE DRAWINGS

FIG. 1 is a schematic cross-sectional view of one example of a nitride semiconductor light-emitting device according to the present invention.

FIG. 2 is a schematic cross-sectional view of another example of the nitride semiconductor light-emitting device according to the present invention.

FIG. 3 is a schematic cross-sectional view of a nitride semiconductor light-emitting diode device according to Example 1.

FIG. 4 shows a theoretical calculation result of a band energy diagram in the vicinity of an AlN intermediate layer of the nitride semiconductor light-emitting diode device according to Example 1.

FIG. 5 shows a theoretical calculation result of a band energy diagram in the vicinity of the AlN intermediate layer, when a thickness of the AlN intermediate layer of the nitride semiconductor light-emitting diode device according to Example 1 is changed.

FIG. 6 is a schematic cross-sectional view of a nitride semiconductor laser device according to Example 3.

FIG. 7 is a schematic cross-sectional view of a nitride semiconductor light-emitting diode device according to a Comparative Example.

FIG. 8 is a schematic plan view when the nitride semiconductor light-emitting diode device according to Comparative Example is viewed from above.

FIG. 9 is a schematic cross-sectional view of a portion in the vicinity of a tunnel junction layer of the nitride semiconductor light-emitting diode device according to Comparative Example.

FIG. 10 shows a theoretical calculation result of a band energy diagram in the vicinity of the tunnel junction layer of the nitride semiconductor light-emitting diode device according to Comparative Example.

FIG. 11 is a schematic cross-sectional view of a conventional nitride semiconductor light-emitting diode device using a tunnel junction.

FIG. 12 is a schematic cross-sectional view of a nitride semiconductor laser device according to Example 4.

FIGS. 13(a) and 13(b) are schematic plan views showing examples of a resist pattern used in fabricating the nitride semiconductor laser device according to Example 4.

FIG. 14 is a schematic cross-sectional view of a nitride semiconductor light-emitting device representing another example of the semiconductor light-emitting device according to the present invention.

FIG. 15 is a schematic cross-sectional view of a nitride semiconductor light-emitting device representing another example of the nitride semiconductor light-emitting device according to the present invention.

FIG. 16 is a schematic cross-sectional view of a nitride semiconductor light-emitting diode device according to Example 5.

FIG. 17 is a schematic cross-sectional view of a nitride semiconductor light-emitting diode device according to Example 7.

FIG. 18 is a schematic cross-sectional view of a conventional nitride semiconductor light-emitting diode device utilizing a surface polariton effect.

### DETAILED DESCRIPTION OF THE INVENTION

An embodiment of the present invention will be described hereinafter. In the drawings of the present invention, the same or corresponding elements have the same reference characters allotted. In addition, in expressing a crystal plane and a direction, a required number should essentially be expressed with a bar over the same. However, since means for expression is restricted, instead of such a representation as providing a bar over a required number, a sign “-” precedes the required number herein.

### First Embodiment

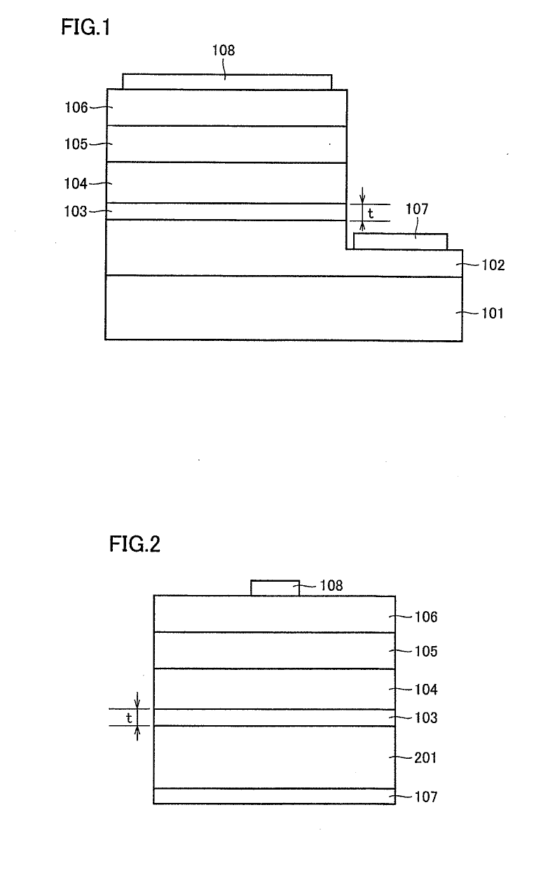

FIG. 1 shows a schematic cross-sectional view of one example of a nitride semiconductor light-emitting device (a nitride semiconductor light-emitting diode device) according to the present invention. Here, the nitride semiconductor light-emitting device having a construction shown in FIG. 1 includes a substrate 101, a first n-type nitride semiconductor layer 102 formed on substrate 101, a nitride semiconductor layer 103 composed of a nitride semiconductor crystal expressed with a formula AlₓGa₁₋ₓN (0<x≦1) and formed on first n-type nitride semiconductor layer 102, a p-type nitride semiconductor layer 104 formed on nitride semiconductor layer 103, and an active layer 105 formed on p-type nitride semiconductor layer 104.

In addition, a first n electrode 107 is formed on a surface of first n-type nitride semiconductor layer 102. Moreover, a second n-type nitride semiconductor layer 106 is formed on active layer 105 and a second n electrode 108 is formed on second n-type nitride semiconductor layer 106.

Here, first n electrode 107 is an anode electrode and a positive bias voltage is externally applied thereto. In addition, second electrode 108 is a cathode electrode and a negative bias voltage is externally applied thereto. By thus applying a bias voltage to the nitride semiconductor light-emitting device, a forward bias voltage is applied to a pn junction including p-type nitride semiconductor layer 104 and second n-type nitride semiconductor layer 106 on opposing sides of active layer 105 and hence light is emitted. Here, however, if first n-type nitride semiconductor layer 102 and p-type nitride semiconductor layer 104 are directly joined to form the pn junction, a reverse bias voltage is applied to this pn junction and a current is less likely to flow. By placing nitride semiconductor layer 103 which will be described in detail below between first n-type nitride semiconductor layer 102 and p-type nitride semiconductor layer 104, however, a current can efficiently flow through this pn junction.

Here, for example, if a hexagonal crystal substrate such as a sapphire substrate, a nitride semiconductor substrate or a silicon carbide substrate is used as substrate 101 and for example first n-type nitride semiconductor layer 102, nitride semiconductor layer 103 and p-type nitride semiconductor layer 104 are successively epitaxially grown on a C plane (a {0001} plane) of that substrate 101, for example, with MOCVD (Metal Organic Chemical Vapor Deposition) or the like, a surface of nitride semiconductor layer 103 composed of a nitride semiconductor crystal expressed with the formula AlₓGa₁₋ₓN (0<x≦1) is the C plane.

If lattice strain is caused, for example, by lattice unmatch or the like in nitride semiconductor layer 103 having such a C plane and composed of a nitride semiconductor crystal expressed with the formula AlₓGa₁₋ₓN (0<x≦1), spontaneous polarization due to piezo electric field occurs in nitride semiconductor layer 103 and a direction of that spontaneous polarization extends along a direction of a C axis. Therefore, the C plane of nitride semiconductor layer 103 exhibits different characteristics between a +C axis side and a −C axis side. Thus, nitride semiconductor layer 103 has a polar plane at each interface with another layer. In the construction shown in FIG. 1, an interface with another layer refers to an interface between first n-type nitride semiconductor layer 102 and nitride semiconductor layer 103 and an interface between nitride semiconductor layer 103 and p-type nitride semiconductor layer 104.

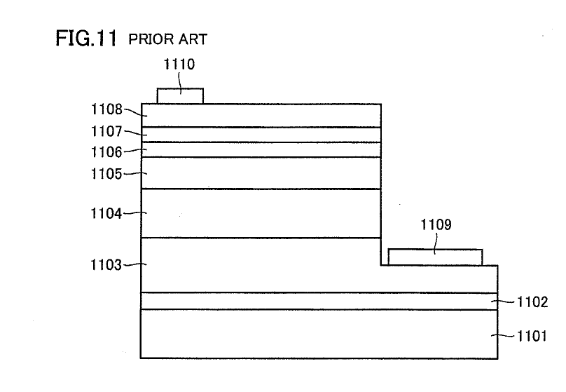

If nitride semiconductor layer 103 has a polar plane as such, energy band of nitride semiconductor layer 103 is bent and a width of a depletion layer between first n-type nitride semiconductor layer 102 and p-type nitride semiconductor layer 104 can be narrowed. Thus, a tunneling current is more likely to flow and a drive voltage of the nitride semiconductor light-emitting device can be lowered as compared with a conventional device having a construction as shown in FIG. 11 and using a tunnel junction.

In addition, for example, a hexagonal crystal substrate can be used as substrate 101, and first n-type nitride semiconductor layer 102, nitride semiconductor layer 103 and p-type nitride semiconductor layer 104 can also successively epitaxially be grown, for example, on a semipolar plane such as an R plane (a {1-102} plane) or a {11-22} plane of that substrate 101, for example, with MOCVD or the like. In this case, the surface of nitride semiconductor layer 103 composed of a nitride semiconductor crystal expressed with the formula AlₓGa₁₋ₓN (0<x≦1) is a semipolar plane such as the R plane (the {1-102} plane) or the {11-22} plane.

Thus, if lattice strain is caused, for example, by lattice unmatch or the like in nitride semiconductor layer 103 composed of a nitride semiconductor crystal expressed with the formula AlₓGa₁₋ₓN (0<x≦1), of which surface is a semipolar plane such as the R plane (the {1-102} plane) or the {11-22} plane as well, spontaneous polarization due to piezo electric field occurs in nitride semiconductor layer 103 and the semipolar planes on opposing surfaces of nitride semiconductor layer 103 exhibit characteristics different from each other. Thus, in this case as well, nitride semiconductor layer 103 has the polar plane.

Therefore, if the surface of nitride semiconductor layer 103 composed of a nitride semiconductor crystal expressed with the formula AlₓGa₁₋ₓN (0<x≦1) is the semipolar plane as well, energy band of nitride semiconductor layer 103 is bent and a width of a depletion layer between first n-type nitride semiconductor layer 102 and p-type nitride semiconductor layer 104 can be narrowed. Thus, a tunneling current is more likely to flow and a drive voltage of the nitride semiconductor light-emitting device can be lowered as compared with a conventional device having a construction as shown in FIG. 11 and using a tunnel junction.

In addition, nitride semiconductor layer 103 may have a polar plane having a prescribed off angle with respect to the C plane or a polar plane having a prescribed off angle with respect to the R plane. It is noted that examples of the polar plane having a prescribed off angle with respect to the C plane above include a surface inclined by 0° or more and less than 45° with respect to the C plane. Meanwhile, examples of the polar plane having a prescribed off angle with respect to the R plane above include a surface inclined by 0° or more and less than 45° with respect to the R plane.

Further, nitride semiconductor layer 103 may have a polar plane having a prescribed off angle with respect to an m plane which is a nonpolar plane or a polar plane having a prescribed off angle with respect to an A plane which is a nonpolar plane. It is noted that examples of the polar plane having a prescribed off angle with respect to the m plane above include a surface inclined by more than 0° and less than 45° with respect to the m plane. Meanwhile, examples of the polar plane having a prescribed off angle with respect to the A plane above include a surface inclined by more than 0° and less than 45° with respect to the A plane.

FIG. 2 shows a schematic cross-sectional view of another example of the nitride semiconductor light-emitting device (the nitride semiconductor light-emitting diode device) according to the present invention. Here, the nitride semiconductor light-emitting device having a construction shown in FIG. 2 is characterized in that a conductive hexagonal n-type nitride semiconductor substrate 201 is employed and the nitride semiconductor light-emitting device is implemented as a nitride semiconductor light-emitting device having a vertical electrode structure by forming first n electrode 107 on a back surface of n-type nitride semiconductor substrate 201.

Namely, the nitride semiconductor light-emitting device having the construction shown in FIG. 2 has n-type nitride semiconductor substrate 201, nitride semiconductor layer 103 formed on n-type nitride semiconductor substrate 201 and composed of a nitride semiconductor crystal expressed with the formula AlₓGa₁₋ₓN (0<x≦1), p-type nitride semiconductor layer 104 formed on nitride semiconductor layer 103, active layer 105 formed on p-type nitride semiconductor layer 104, and second n-type nitride semiconductor layer 106 formed on active layer 105, first n electrode 107 is formed on the back surface of n-type nitride semiconductor substrate 201, and second n electrode 108 is formed on second n-type nitride semiconductor layer 106.

In the nitride semiconductor light-emitting device having the construction shown in FIG. 2 as well, if nitride semiconductor layer 103 and p-type nitride semiconductor layer 104 are successively formed by epitaxial growth, for example, on the C plane (the {0001} plane) of n-type nitride semiconductor substrate 201, for example, with MOCVD or the like, the surface of nitride semiconductor layer 103 composed of a nitride semiconductor crystal expressed with the formula AlₓGa₁₋ₓN (0x≦1) is the C plane.

Therefore, if lattice strain is caused, for example, by lattice unmatch or the like in nitride semiconductor layer 103 composed of a nitride semiconductor crystal having such a C plane and expressed with the formula AlₓGa₁₋ₓN (0<x≦1), nitride semiconductor layer 103 has a polar plane for the reason the same as above.

Then, in nitride semiconductor layer 103 having the polar plane, energy band is bent and a width of a depletion layer between n-type nitride semiconductor substrate 201 and p-type nitride semiconductor layer 104 can be narrowed and hence a tunneling current is more likely to flow. Therefore, in the nitride semiconductor light-emitting device having the construction shown in FIG. 2 as well, a drive voltage of the nitride semiconductor light-emitting device can be lowered as compared with a conventional device having a construction as shown in FIG. 11 and using a tunnel junction.

In addition, nitride semiconductor layer 103 and p-type nitride semiconductor layer 104 can also successively be epitaxially grown on a semipolar plane of n-type nitride semiconductor substrate 201 such as the R plane ({the 1-102} plane) or the {11-22} plane, for example, with MOCVD or the like, and in this case, the surface of nitride semiconductor layer 103 composed of a nitride semiconductor crystal expressed with the formula AlₓGa₁₋ₓN (0<x≦1) is the semipolar plane such as the R plane (the {1-102} plane) or the {11-22} plane as above.

Thus, if lattice strain is caused, for example, by lattice unmatch or the like in nitride semiconductor layer 103 having the semipolar plane as the surface and composed of a nitride semiconductor crystal expressed with the formula AlₓGa₁₋ₓN (0x≦1), spontaneous polarization due to piezo electric field occurs in nitride semiconductor layer 103 and the semipolar planes on opposing surfaces of nitride semiconductor layer 103 exhibit characteristics different from each other. Thus, nitride semiconductor layer 103 has the polar plane. If nitride semiconductor layer 103 has the polar plane, energy band is bent in nitride semiconductor layer 103 and a width of a depletion layer between n-type nitride semiconductor substrate 201 and p-type nitride semiconductor layer 104 can be narrowed and hence a tunneling current is more likely to flow. Therefore, in this case as well, a drive voltage of the nitride semiconductor light-emitting device can be lowered as compared with a conventional device having a construction as shown in FIG. 11 and using a tunnel junction.

In the present invention, for example, a substrate composed of a hexagonal semiconductor crystal such as a sapphire substrate, a nitride semiconductor substrate or a silicon carbide substrate can be used as substrate 101 as described above. Among these, if a nitride semiconductor substrate is used as substrate 101, difference in lattice constant from a nitride semiconductor layer to be formed on substrate 101 becomes small and hence the nitride semiconductor layer having good crystallinity can be obtained. It is noted that, for example, a substrate composed of a group III nitride semiconductor crystal expressed with a formula Alₓ₀Ga_{y0}In_{z0}N (0≦x0≦1, 0≦y0≦1, 0≦z0≦1, x0+y0+z0=1) can be used as the nitride semiconductor substrate.

Alternatively, in the present invention, for example, a substrate formed by doping a group III nitride semiconductor crystal expressed with the formula Alₓ₀In_{y0}Ga_{z0}N (0≦x0≦1, 0≦y0≦1, 0≦z0≦1, x0+y0+z0=1) above with an n-type impurity, or the like can be used as n-type nitride semiconductor substrate 201.

In the formula above, Al represents aluminum, In represents indium, Ga represents gallium, x0 represents an Al composition ratio, y0 represents an In composition ratio, and z0 represents a Ga composition ratio. In addition, for example, silicon and/or germanium or the like can be used as an n-type impurity.

Further, in substrate 101 and n-type nitride semiconductor substrate 201 implemented by the nitride semiconductor substrate above, approximately 10 atomic % or less nitrogen atoms may be substituted by atoms of As (arsenic), P (phosphorus), Sb (antimony), or the like, so long as a hexagonal crystal is maintained.

For example, a conventionally known n-type nitride semiconductor can be used for first n-type nitride semiconductor layer 102, and for example, a single layer, a plurality of layers or the like formed by doping a group III nitride semiconductor crystal expressed with a formula Alₓ₁In_{y1}Ga_{z1}N (0≦x1≦1, 0≦y1≦1, 0≦z1≦1, x1+y1+z1=1) with an n-type impurity can be used. In the formula above, Al represents aluminum, In represents indium, Ga represents gallium, x1 represents an Al composition ratio, y1 represents an In composition ratio, and z1 represents a Ga composition ratio. In addition, for example, silicon and/or germanium or the like can be used as an n-type impurity. From a point of view of providing nitride semiconductor layer 103 with the polar plane, a material different from that for nitride semiconductor layer 103 is preferably used for first n-type nitride semiconductor layer 102.

In addition, one or more other layer such as a buffer layer or a thin non-doped layer (for example, a non-doped layer having a thickness not greater than 0.5 μm) may be or may not be included between first n-type nitride semiconductor layer 102 and substrate 101 and between nitride semiconductor layer 103 and n-type nitride semiconductor substrate 201.

In addition, as described above, the group III nitride semiconductor crystal expressed with the formula AlₓGa₁₋ₓN (0<x≦1) and having the polar plane is used for nitride semiconductor layer 103. Here, Al represents aluminum, Ga represents gallium, x represents an Al composition ratio, and (1−x) represents a Ga composition ratio. It is noted that nitride semiconductor layer 103 may be any of an n-type and a p-type or non-doped.

Nitride semiconductor layer 103 preferably has a thickness t not smaller than 0.5 nm and not greater than 30 nm. When nitride semiconductor layer 103 has thickness t not smaller than 0.5 nm, nitride semiconductor layer 103 is more likely to be a layer of a uniform in-plane thickness. When it has a thickness not greater than 30 nm, deterioration in crystallinity of nitride semiconductor layer 103 due to generation of a crack or the like caused by lattice strain in nitride semiconductor layer 103 is less likely.

Though one or more other layer may be included between nitride semiconductor layer 103 and first n-type nitride semiconductor layer 102, nitride semiconductor layer 103 and first n-type nitride semiconductor layer 102 are preferably in contact with each other from a point of view of narrowing a width of a depletion layer.

Meanwhile, for example, a conventionally known p-type nitride semiconductor can be used for p-type nitride semiconductor layer 104, and for example, a single layer, a plurality of layers or the like formed by doping a group III nitride semiconductor crystal expressed with a formula Alₓ₂In_{y2}Ga_{z2}N (0≦x2≦1, 0≦y2≦1, 0≦z2≦1, x2+y2+z2=1) with a p-type impurity can be used. In the formula above, Al represents aluminum, In represents indium, Ga represents gallium, x2 represents an Al composition ratio, y2 represents an In composition ratio, and z2 represents a Ga composition ratio. In addition, for example, magnesium and/or zinc or the like can be used as a p-type impurity. From a point of view of providing nitride semiconductor layer 103 with a polar plane, a material different from that for nitride semiconductor layer 103 is preferably used for p-type nitride semiconductor layer 104.

Though one or more other layer may be included between p-type nitride semiconductor layer 104 and nitride semiconductor layer 103, p-type nitride semiconductor layer 104 and nitride semiconductor layer 103 are preferably in contact with each other from a point of view of narrowing a width of a depletion layer.

Meanwhile, for example, a conventionally known nitride semiconductor can be used for active layer 105, and for example, a single layer, a plurality of layers or the like formed of a non-doped group III nitride semiconductor crystal expressed with a formula Alₓ₃In_{y3}Ga_{z3}N (0≦x3≦1, 0≦y3≦1, 0≦z3≦1, x3+y3+z3=1) or formed by doping the group III nitride semiconductor crystal expressed with this formula with at least one of a p-type impurity and an n-type impurity can be used. In the formula above, Al represents aluminum, In represents indium, Ga represents gallium, x3 represents an Al composition ratio, y3 represents an In composition ratio, and z3 represents a Ga composition ratio. In addition, active layer 105 may be constructed to have a conventionally known single quantum well (SQW) structure or multiple quantum well (MQW) structure.

One or more other layer may be or may not be included between active layer 105 and p-type nitride semiconductor layer 104.

Meanwhile, for example, a conventionally known n-type nitride semiconductor can be used for second n-type nitride semiconductor layer 106, and for example, a single layer, a plurality of layers or the like formed by doping a group III nitride semiconductor crystal expressed with a formula Alₓ₄In_{y4}Ga_{z4}N (0≦x4≦1, 0≦y4≦1, 0≦z4≦1, x4+y4+z4=1) with an n-type impurity can be used. In the formula above, Al represents aluminum, In represents indium, Ga represents gallium, x4 represents an Al composition ratio, y4 represents an In composition ratio, and z4 represents a Ga composition ratio. In addition, for example, silicon and/or germanium or the like can be used as an n-type impurity.

One or more other layer may be or may not be included between second n-type nitride semiconductor layer 106 and active layer 105.

Meanwhile, for example, a conventionally known metal or the like capable of establishing ohmic contact with first n-type nitride semiconductor layer 102 can be used for first n electrode 107. For example, a conventionally known metal or the like capable of establishing ohmic contact with second n-type nitride semiconductor layer 106 can be used for first n electrode 108. It is noted that first n electrode 107 and second n electrode 108 may be composed of an identical metal or of different metals respectively.

In each of the nitride semiconductor light-emitting devices having the constructions shown in FIGS. 1 and 2, second n-type nitride semiconductor layer 106 is formed after active layer 105 is formed. If second n-type nitride semiconductor layer 106 is formed at a low temperature, however, higher resistance and significant deterioration in crystallinity of second n-type nitride semiconductor layer 106 can be suppressed because second n-type nitride semiconductor layer 106 is an n-type nitride semiconductor layer. Further, since second n-type nitride semiconductor layer 106 can be formed at a low temperature, thermal damage to active layer 105 can also be mitigated.

The group III nitride semiconductor crystal containing In has been known to have quite a low decomposition temperature as compared with the group III nitride semiconductor crystal not containing In. For example, a nitride semiconductor crystal not containing In such as GaN, AlN and a mixed crystal thereof is relatively stable at a high temperature around 1000° C., whereas InN decomposes even at a low temperature approximately from 600 to 700° C. Therefore, crystallinity of the group III nitride semiconductor crystal containing In expressed, for example, with a formula In_{y}Ga_{1-y}N generally deteriorates at a temperature exceeding 1000° C., although depending on In composition ratio y. When light in a long wavelength range such as green light or red light is to be emitted, In composition ratio y in the group III nitride semiconductor crystal containing In expressed with the formula In_{y}Ga_{1-y}N should be high approximately from 0.15 to 0.4, however, in such a case, deterioration in crystallinity in connection with a temperature of the nitride semiconductor crystal containing In is more likely.

In the conventional nitride semiconductor light-emitting device having the construction shown in FIG. 11, after active layer 1104 containing InGaN is formed, for example, at a low temperature approximately from 600° C. to 800° C., the p-type nitride semiconductor layer such as Mg-doped p-type GaN layer 1105 should be formed at a high temperature exceeding 1000° C.

In the conventional nitride semiconductor light-emitting device having the construction shown in FIG. 11, thermal damage due to a temperature during temperature increase for forming the p-type nitride semiconductor layer such as Mg-doped p-type GaN layer 1105 at a high temperature and during formation thereof is incurred on active layer 1104 and hence crystallinity of active layer 1104 significantly deteriorates. On the other hand, if the In composition ratio in InGaN forming active layer 1104 is not lower than 0.15 and particularly not lower than 0.2, the p-type nitride semiconductor layer such as Mg-doped p-type GaN layer 1105 should be formed at a low temperature, which leads to higher resistance and deterioration in crystallinity of the p-type nitride semiconductor layer and hence increase in a drive voltage.

In each of the nitride semiconductor light-emitting devices having the constructions shown in FIGS. 1 and 2, however, second n-type nitride semiconductor layer 106 is formed after formation of active layer 105 and it is not necessary to form a p-type nitride semiconductor layer. Therefore, for example, in a case where active layer 105 has a group III nitride semiconductor layer containing In, if the In composition ratio is not lower than 0.15 and in particular not lower than 0.2, such a construction that second n-type nitride semiconductor layer 106 is formed after formation of active layer 105 and a p-type nitride semiconductor layer is not formed as shown in FIGS. 1 and 2 is considered as effective. Though the upper limit of the In composition ratio in active layer 105 is not particularly limited in the present invention, light emission efficiency may be lowered if the In composition ratio in active layer 105 exceeds 0.4, and therefore the In composition ratio in active layer 105 is preferably not higher than 0.4.

In addition, though a construction of a nitride semiconductor light-emitting diode device representing the nitride semiconductor light-emitting device according to the present invention has mainly been described above, the construction above is naturally applicable also to a nitride semiconductor laser device and the like.

### Second Embodiment

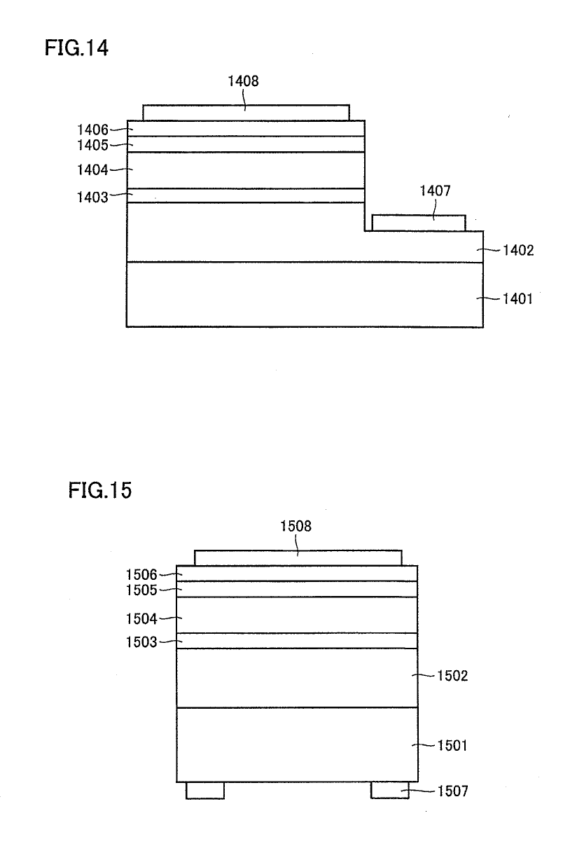

FIG. 14 shows a schematic cross-sectional view of a nitride semiconductor light-emitting device (a nitride semiconductor light-emitting diode device) representing one example of the semiconductor light-emitting device according to the present invention. This nitride semiconductor light-emitting device includes a substrate 1401, a first lower layer 1402 formed on substrate 1401 and made of a nitride semiconductor, an intermediate layer 1403 formed on first lower layer 1402 and made of a nitride semiconductor, a second lower layer 1404 formed on intermediate layer 1403 and made of a nitride semiconductor, an active layer 1405 formed on second lower layer 1404 and made of a nitride semiconductor, and an upper layer 1406 formed on active layer 1405 and made of a nitride semiconductor.

In addition, a first electrode for n-type 1407 is formed in contact with a partially exposed surface of first lower layer 1402, and a second electrode for n-type 1408 is formed in contact with a surface of upper layer 1406.

First lower layer 1402 includes a single nitride semiconductor layer or a plurality of nitride semiconductor layers and it has n-type conductivity as a whole. Here, having n-type conductivity as a whole means having such a characteristic that a layer having n-type conductivity is mainly included and even though such a layer as a thin non-doped layer is arranged in between layers or at an end, electrons mainly conduct as a whole. Second lower layer 1404 includes a single nitride semiconductor layer or a plurality of nitride semiconductor layers and it has p-type conductivity as a whole. Here, having p-type conductivity as a whole means having such a characteristic that a layer having p-type conductivity is mainly included and even though such a layer as a thin non-doped layer is arranged in between layers or at an end, holes mainly conduct as a whole. Upper layer 1406 includes a single nitride semiconductor layer or a plurality of nitride semiconductor layers and it has n-type conductivity as a whole.

First electrode for n-type 1407 is used as an anode electrode and second electrode for n-type 1408 is used as a cathode electrode. Namely, while the nitride semiconductor light-emitting device having the construction shown in FIG. 14 is driven, a positive voltage is externally applied to first electrode for n-type 1407 and a negative voltage is applied to second electrode for n-type 1408. Therefore, a current path from the positive voltage to the negative voltage is routed from first electrode for n-type 1407 through first lower layer 1402 having n-type conductivity as a whole, intermediate layer 1403, second lower layer 1404 having p-type conductivity as a whole, active layer 1405, and upper layer 1406 to second electrode for n-type 1408.

By thus biasing the nitride semiconductor light-emitting device having he construction shown in FIG. 14, forward bias is applied to the pn junction formed by second lower layer 1404 having p-type conductivity as a whole and upper layer 1406 having n-type conductivity as a whole which sandwich active layer 1405, and light is emitted by normally driving the nitride semiconductor light-emitting diode device. Here, a thickness or a doping amount of second lower layer 1404 having p-type conductivity as a whole can be selected as appropriate, regardless of coupling between surface plasmon and light. Therefore, second lower layer 1404 can be doped with a p-type impurity at sufficiently high concentration and sufficient holes can be supplied to active layer 1405 while the nitride semiconductor light-emitting device is driven.

A thickness of upper layer 1406 having n-type conductivity as a whole should be restricted at least to a thickness not greater than 40 nm for coupling between surface plasmon of second electrode for n-type 1408 and light from active layer 1405. Doping of a nitride semiconductor in upper layer 1406 with an n-type impurity is easier than in a case of doping with a p-type impurity.

More specifically, regarding a p-type impurity (normally, Mg), in order to attain desired carrier (hole) concentration, a nitride semiconductor should be doped with an excessive amount of impurity. In addition, since Mg tends to diffuse into another layer, it is difficult to generate sufficient carriers only in a very thin layer having a thickness not greater than 40 nm. Moreover, if Mg diffuses into (or is added to) the active layer in the nitride semiconductor light-emitting device, the problem of lowering in quality of the active layer also arises. However, carriers generated in upper layer 1406 having n-type conductivity as a whole and having a very small thickness not greater than 40 nm are electrons, and hence such a problem as in the case of a layer having p-type conductivity where carriers are holes is much less likely to occur.

Namely, in a nitride semiconductor, an n-type impurity (normally, Si) can generate carriers (electrons) substantially as much as the doping amount, and even if Si diffuses into the active layer, the problem of lowering in quality of the active layer is less likely to occur. In contrast, there is also a report that light emission efficiency is improved by adding Si to the active layer (Jpn. J. Appl. Phys., Vol. 37 (1998) pp. L1362-L1364). It is not disadvantage to dope the active layer itself with an n-type impurity, and in that case, it is not necessary either to quickly switch doping during crystal growth in a plurality of layers. Therefore, manufacturing of a nitride semiconductor light-emitting device is facilitated. It is noted that an active layer herein means layers from a lowermost well layer to an uppermost well layer if it has a multiple quantum well structure and means only a well layer if it has a single quantum well structure.

While the nitride semiconductor light-emitting device having the construction shown in FIG. 14 is driven, reverse bias is applied to an additional pn junction formed by second lower layer 1404 having p-type conductivity as a whole and first lower layer 1402 having n-type conductivity as a whole that sandwich intermediate layer 1403. Here, in the case of a normal pn junction, a current is less likely to flow in a direction of reverse bias, however, a current can efficiently flow through the additional pn junction by utilizing a construction allowing effective flow of a tunneling current (a tunnel junction). To that end, the additional pn junction sandwiching intermediate layer 1403 is preferably specially constructed as will be exemplified later.

In second electrode for n-type 1408, at least a surface in contact with upper layer 1406 (an interface) is composed of Ag (an Ag interface). In addition, upper layer 1406 is set to have a thickness not greater than 40 nm. Since a semiconductor-Ag interface can thus be arranged within near field of active layer 1405, light from active layer 1405 can readily be coupled to surface plasmon at the Ag interface of second electrode for n-type 1408 and light emission efficiency can be improved. It is noted that a thickness of upper layer 1406 is preferably set to 20 nm or smaller and it can be set typically to approximately 10 nm.

According to the feature of the nitride semiconductor light-emitting device having the construction shown in FIG. 14 as described above, holes and electrons can efficiently be injected into active layer 1405 when a current is injected into the nitride semiconductor light-emitting device and thus the nitride semiconductor light-emitting device is driven. A sufficient quantity of light can thus be emitted from active layer 1405 and surface plasmon polariton (SPP) resulted from coupling of light from active layer 1405 to surface plasmon can be produced at the Ag interface of second electrode for n-type 1408. Therefore, in the nitride semiconductor light-emitting device having the construction shown in FIG. 14, SPP can efficiently be produced by current injection and increase in a spontaneous emission rate in light emission from active layer 1405 as in Non-Patent Document 2 can be realized, and thus high light emission efficiency can be obtained.

It is noted that the Ag interface of second electrode for n-type 1408 in contact with upper layer 1406 made of an n-type nitride semiconductor is normally uneven but it microscopically includes grain boundaries or small irregularities in many cases. Therefore, SPP produced as above is modulated as it propagates along the Ag interface of second electrode for n-type 1408 and converted again to light, and that light is extracted to the outside. Taking into account this phenomenon, irregularities or patterns may artificially be provided on the Ag interface of second electrode for n-type 1408. In addition, since the Ag interface of second electrode for n-type 1408 can form good ohmic contact with upper layer 1406 made of an n-type nitride semiconductor, carriers can thus well be injected into active layer 1405, which is also improvement on the conventional art.

Regarding combination between an active layer and an electrode material, the following are possible. Namely, SPP produced by light emission from the active layer relates to a surface plasmon frequency of a metal. Therefore, use of Ag (a wavelength of light corresponding to a surface plasmon frequency: approximately 440 nm) for an interface of an electrode in contact with a semiconductor is particularly effective to the active layer emitting light in a blue region (a wavelength from 440 to 500 nm) and a light emission efficiency improvement effect can be expected even in an active layer emitting light on a slightly longer wavelength side (a wavelength from 500 to 600 nm) than the former.

Alternatively, use of Al (a wavelength of light corresponding to a surface plasmon frequency: approximately 230 nm) for an interface of an electrode in contact with a semiconductor is particularly effective to an active layer emitting light in a deep ultraviolet region (a wavelength from 230 nm to 300 nm) and a light emission efficiency improvement effect can be expected even in an active layer emitting light on a slightly longer wavelength side (a wavelength from 300 to 400 nm) than the former.

Further alternatively, use of Au (a wavelength of light corresponding to a surface plasmon frequency: approximately 540 nm) for an interface of an electrode in contact with a semiconductor is particularly effective to an active layer emitting light in a region from green to red (a wavelength from 540 to 600 nm) and a light emission efficiency improvement effect can be expected even in an active layer emitting light on a slightly longer wavelength side (a wavelength from 600 to 700 nm) than the former.

Since Al and Au can form good ohmic contact with an n-type nitride semiconductor as in the case of Ag described above, carriers can well be injected into the active layer while the nitride semiconductor light-emitting diode device is driven. It is noted that Ag, Al and Au can generally form good ohmic contact with an n-type layer made of a compound semiconductor, without limited to a nitride semiconductor. Therefore, Ag, Al and Au are useful as electrode materials for general semiconductor light-emitting devices including a compound semiconductor other than the nitride semiconductor.

In the case of an alloy mainly composed of Ag with other components being mixed, it is difficult to expect how a surface plasmon frequency varies, because there are many unknown points. For example, however, if an alloy containing Ag as a major component (a main component) is used as a material for second electrode for n-type 1408 of the nitride semiconductor light-emitting device having the construction shown in FIG. 14, it is believed that an effect of the present invention can be expected.

Therefore, it is considered that at least an Ag alloy (of which Ag atom concentration is not lower than 50 atomic %) can be used as a material for second electrode for n-type 1408 of the nitride semiconductor light-emitting device having the construction shown in FIG. 14.

In addition, for the reasons the same as those for the Ag alloy described above, it is considered that an Al alloy (of which Al atom concentration is not lower than 50 atomic %) and an Au alloy (of which Au atom concentration is not lower than 50 atomic %) can also be used as a material for second electrode for n-type 1408 of the nitride semiconductor light-emitting device having the construction shown in FIG. 14. Moreover, a material having a surface plasmon frequency corresponding to a wavelength of light emitted from the active layer can also be selected for use as an electrode material capable of exciting surface plasmon as appropriate, other than Ag, the Ag alloy, Al, the Al alloy, Au, and the Au alloy described above.

The additional pn junction will now be discussed. In the nitride semiconductor light-emitting device having the construction shown in FIG. 14, if a hexagonal semiconductor crystal substrate such as a sapphire substrate, a nitride semiconductor substrate or a silicon carbide substrate is used as substrate 1401 and first lower layer 1402, intermediate layer 1403 and second lower layer 1404 are successively epitaxially grown on a C plane (a {0001} plane) thereof with MOCVD (Metal Organic Chemical

Vapor Deposition) or the like, respective surfaces of first lower layer 1402, intermediate layer 1403 and second lower layer 1404 that were epitaxially grown are also the C planes. Such a C plane orientation is most general in a nitride semiconductor light-emitting device.

Here, if lattice strain is caused, for example, by lattice unmatch or the like in intermediate layer 1403 having such a C plane, piezo electric field due to piezoelectric polarization is produced in intermediate layer 1403 and a direction of polarization extends along a direction of a C axis (a <0001> direction). Consequently, the C plane of intermediate layer 1403 exhibits different electric characteristics between a +C axis side and a −C axis side and thus intermediate layer 1403 has a lower interface and an upper interface that are polar planes different in polarity. Here, the lower interface of intermediate layer 1403 is a surface in contact with first lower layer 1402 having n-type conductivity, and the upper interface of intermediate layer 1403 is a surface in contact with second lower layer 1404 having p-type conductivity.

If intermediate layer 1403 having such a polar plane has tensile strain as tensile stress due to difference in lattice constant from each of first lower layer 1402 and second lower layer 1404 is applied thereto, energy band of intermediate layer 1403 is bent and a width of a depletion layer between first lower layer 1402 and second lower layer 1404 can be narrowed. Consequently, a tunneling current is more likely to flow between first lower layer 1402 and second lower layer 1404 through the additional pn junction to which reverse bias is applied, and a drive voltage of the nitride semiconductor light-emitting device can be lowered as compared with the construction not including intermediate layer 1403. For example, if first lower layer 1402 and second lower layer 1404 are formed of GaN or AlGaN low in Al concentration and intermediate layer 1403 is formed of AlN or AlGaN high in Al concentration, such a construction as above that intermediate layer 1403 has a polar plane and tensile strain can be obtained, because lattice constant of AlGaN becomes smaller with the increase in Al concentration thereof.

In addition, a hexagonal semiconductor crystal substrate can be used as substrate 1401, and first lower layer 1402, intermediate layer 1403 and second lower layer 1404 can also successively epitaxially be grown on a semipolar plane such as an R plane (a {1-102} plane) or a {11-22} plane of that substrate 1401 with MOCVD or the like. In this case, the surface of intermediate layer 1403 is also a semipolar plane such as the R plane (the {1-102} plane) or the {11-22} plane. If lattice strain is thus caused by lattice unmatch or the like in intermediate layer 1403 having the semipolar plane such as the R plane (the {1-102} plane) or the {11-22} plane as the surface as well, piezo electric field due to piezoelectric polarization is produced and the lower interface and the upper interface that are the semipolar planes of intermediate layer 1403 exhibit electric characteristics different from each other.

In addition, the surface of substrate 1401 (the surface on which a nitride semiconductor layer is to be grown) may be a plane having an off angle with respect to the C plane or the R plane. Examples of the surface of substrate 1401 in this case include a surface inclined by 0° or more and less than 45° with respect to the C plane or a surface inclined by 0° or more and less than 45° with respect to the R plane.

Moreover, the surface of substrate 1401 may be a plane having an off angle with respect to a nonpolar plane of the M plane (the {10-10} plane) or the A plane (the {11-20} plane).

Examples of the surface of substrate 1401 in this case include a surface inclined by more than 0° and less than 45° with respect to the M plane or a surface inclined by more than 0° and less than 45° with respect to the A plane.

As described above, if the surface of substrate 1401 is a surface having an off angle with respect to the C plane, the R plane, the M plane, or the A plane, a drive voltage of the nitride semiconductor light-emitting device can be lowered as in the case where the surface of substrate 1401 is the C plane.

Further, for facilitating reverse bias current flow through the additional pn junction, it is also effective to dope that junction portion at high concentration. For example, first lower layer 1402 and second lower layer 1404 can be joined to each other without providing intermediate layer 1403, and at least in the vicinity of the junction, concentration of an n-type impurity in first lower layer 1402 can be set preferably in a range from 1×10¹⁸ to 1×10²¹/cm³ and more preferably in a range from 1×10¹⁹ to 1×10²⁰/cm³ and concentration of a p-type impurity in second lower layer 1404 can be set preferably in a range from 1×10¹⁹ to 1×10²⁰/cm³ and more preferably in a range from 3×10¹⁹ to 3×10²⁰/cm³. Here, the vicinity of the junction refers to an area to a depth of approximately 50 nm from a junction interface, where a tunneling current can be accelerated by doping. In addition, in this case, a synergistic effect may be obtained by providing intermediate layer 1403 composed as described above, and only an effect of high-concentration doping can also be utilized with or without an intermediate layer having a composition different from the composition described above.

FIG. 15 shows a schematic cross-sectional view of a nitride semiconductor light-emitting device (a nitride semiconductor light-emitting diode device) representing another example of the nitride semiconductor light-emitting device according to the present invention. The nitride semiconductor light-emitting device having the construction shown in FIG. 15 is characterized in that an n-type substrate 1501 composed of a hexagonal nitride semiconductor having n-type conductivity is used and the nitride semiconductor light-emitting device is implemented as a nitride semiconductor light-emitting device having a vertical electrode structure by forming a first electrode for n-type 1507 on a back surface of n-type substrate 1501.

Namely, the nitride semiconductor light-emitting device having the construction shown in FIG. 15 includes n-type substrate 1501, a first lower layer 1502 formed on n-type substrate 1501, an intermediate layer 1503 formed on first lower layer 1502, a second lower layer 1504 formed on intermediate layer 1503, an active layer 1505 formed on second lower layer 1504, and an upper layer 1506 formed on active layer 1505. Then, first electrode for n-type 1507 is formed on the back surface of n-type substrate 1501 in contact therewith, and a second electrode for n-type 1508 is formed on a surface of upper layer 1506 in contact therewith.

In the nitride semiconductor light-emitting device having the construction shown in FIG. 15, a current path from a positive voltage to a negative voltage is routed from first electrode for n-type 1507 through n-type substrate 1501, first lower layer 1502 having n-type conductivity as a whole, intermediate layer 1503, second lower layer 1504 having p-type conductivity as a whole, active layer 1505, and upper layer 1506 to second electrode for n-type 1508.

Since the description other than the above of the nitride semiconductor light-emitting device having the construction shown in FIG. 15 is the same as that of the nitride semiconductor light-emitting device having the construction shown in FIG. 14, description thereof will not be provided.

If the semiconductor light-emitting device according to the present invention is in particular the nitride semiconductor light-emitting device having a construction as shown in FIGS. 14 and 15 in which nitride semiconductor layers are stacked on a substrate, a hexagonal semiconductor crystal substrate such as a sapphire substrate, a nitride semiconductor substrate or a silicon carbide substrate as described above can be used as substrate 1401, 1501. Among these, use of a nitride semiconductor substrate as substrate 1401, 1501 for the nitride semiconductor light-emitting device tends to achieve good crystallinity in the nitride semiconductor layer, because difference in physical property between substrate 1401, 1501 and the nitride semiconductor layer, such as smaller difference in lattice constant between substrate 1401, 1501 and the nitride semiconductor layer stacked thereon, can be smaller.

For example, a substrate composed of a group III nitride semiconductor crystal expressed with a formula Alₓ₅Ga_{y5}In_{z5}N (0≦x5≦1, 0≦y5≦1, 0≦z5≦1, x5+y5+z5=1) can be used as the nitride semiconductor substrate.

In addition, for example, a group III nitride semiconductor crystal expressed with a formula Alₓ₆In_{y6}Ga_{z6}N (0≦x6≦1, 0≦y6≦1, 0≦z6≦1, x6+y6+z6=1) can be used independently for a layer to be stacked on substrate 1401, 1501 (first lower layer 1402, 1502, intermediate layer 1502, 1503, second lower layer 1404, 1504, active layer 1405, 1505, and upper layer 1406, 1506). Si and/or Ge or the like can be used as an n-type impurity and a VI group element such as O and Se can also be used. Mg and/or Zn or the like can be used as a p-type impurity. In addition, for example, active layer 1405, 1505 may be constructed to have a conventionally known single quantum well (SQW) structure or multiple quantum well (MQW) structure.

For example, a conventionally known metal or the like capable of forming ohmic contact with n-type first lower layer 1402 or n-type substrate 1501 can be used for first n electrode 1407, 1507 in the nitride semiconductor light-emitting device having the construction shown in FIGS. 14 and 15. In each of the nitride semiconductor light-emitting devices having the constructions shown in FIGS. 14 and 15, upper layer 1406, 1506 can be formed after active layer 1405, 1505 is formed. If upper layer 1406, 1506 is formed at a low temperature, however, higher resistance and significant deterioration in crystallinity of upper layer 1406, 1506 can be suppressed because upper layer 1406, 1506 is an n-type nitride semiconductor layer. Further, if upper layer 1406, 1506 is formed at a low temperature, thermal damage to active layer 1405, 1505 can also be mitigated.

The group III nitride semiconductor crystal containing In has been known to have quite a low decomposition temperature as compared with a group III nitride semiconductor crystal not containing In. For example, a nitride semiconductor crystal not containing In such as GaN, AlN and a mixed crystal thereof is relatively stable at a high temperature around 1000° C., whereas InN decomposes even at a low temperature approximately from 600 to 700° C. Therefore, crystallinity of the group III nitride semiconductor crystal containing In expressed, for example, with a formula In_{y}Ga_{1-y}N generally deteriorates at a temperature exceeding 1000° C., although depending on In composition ratio y. When light in a long wavelength range such as green light or red light is to be emitted from active layer 1405, 1505, In composition ratio y of the group III nitride semiconductor crystal containing In expressed with the formula In_{y}Ga_{1-y}N should be high approximately from 0.15 to 0.4, however, in such a case, deterioration in crystallinity in connection with a temperature of the nitride semiconductor crystal containing In is more likely.

### EXAMPLES

### Example 1

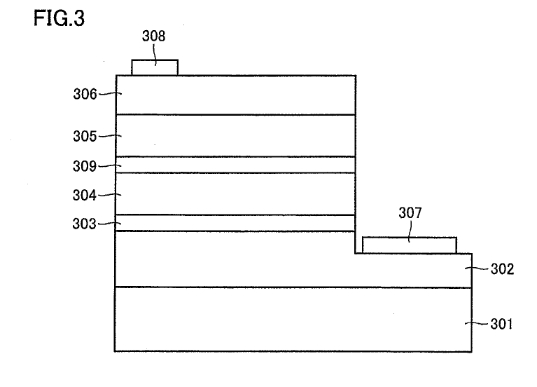

FIG. 3 shows a schematic cross-sectional view of a nitride semiconductor light-emitting diode device according to Example 1 representing one example of the nitride semiconductor light-emitting device according to the present invention. Here, the nitride semiconductor light-emitting diode device according to Example 1 has such a construction that a first n-type GaN layer 302 having a thickness of 5 μm, an AlN intermediate layer 303 having a thickness of 2.5 nm, a p-type GaN layer 304 having a thickness of 0.3 μm, a p-type Al_{0.1}Ga_{0.9}N carrier blocking layer 309 having a thickness of 10 nm, a multiple quantum well active later 305 having a thickness of 0.168 μm, and a second n-type GaN layer 306 having a thickness of 0.3 μm are stacked in this order on a sapphire substrate 301 having a thickness of 400 μm, in which a first n electrode 307 is formed on first n-type GaN layer 302 and a second n electrode 308 is formed on second n-type GaN layer 306.

Here, multiple quantum well active later 305 has such a construction that a non-doped GaN layer having a thickness of 60 nm, a stack in which a non-doped In_{0.02}Ga_{0.98}N barrier layer having a thickness of 8 nm and a non-doped In_{0.2}Ga_{0.8}N well layer having a thickness of 4 nm are alternately stacked four times, and a non-doped GaN layer having a thickness of 60 nm are stacked in this order from the side of p-type Al_{0.1}Ga_{0.9}N carrier blocking layer 309.

In addition, first n electrode 307 is formed in contact with first n-type GaN layer 302, and it has such a construction that a hafnium film (a thickness of 30 nm), an aluminum film (a thickness of 200 nm), a molybdenum film (a thickness of 30 nm), a platinum film (a thickness of 50 nm), and a gold film (a thickness of 200 nm) are stacked in this order from the side of first n-type GaN layer 302.

Second n electrode 308 is identical in structure to first n electrode 307.

The nitride semiconductor light-emitting diode device according to Example 1 having the construction above is manufactured as follows.

Initially, using an MOCVD film deposition apparatus, first n-type GaN layer 302, AlN intermediate layer 303, p-type GaN layer 304, p-type Al_{0.1}Ga_{0.9}N carrier blocking layer 309, multiple quantum well active later 305, and second n-type GaN layer 306 are epitaxially grown in this order with MOCVD on the (0001) plane which is the C plane of sapphire substrate 301 having a surface having a diameter of 2 inches and a thickness of 400 μm. Here, ammonia is used as a nitrogen source, TMG (trimethylgallium) is used as a gallium source, TMI (trimethylindium) is used as an indium source, TMA (trimethylaluminum) is used as an aluminum source, Cp2Mg (bis(cyclopentadienyl)magnesium) is used as a source of magnesium which is a p-type impurity, and silane is used as a source of silicon which is an n-type impurity.

It is noted that carrier density in each of first n-type GaN layer 302 and second n-type GaN layer 306 is approximately 1×10¹⁸ cm⁻³. In addition, carrier density in p-type GaN layer 304 is approximately 4×10¹⁷ cm⁻³. AlN intermediate layer 303 is not doped with a p-type impurity and an n-type impurity intentionally.

First n-type GaN layer 302 is formed by setting a temperature of sapphire substrate 301 to 1125° C., and AlN intermediate layer 303, p-type GaN layer 304 and p-type Al_{0.1}Ga_{0.9}N carrier blocking layer 309 are also successively formed by setting a temperature of sapphire substrate 301 to 1125° C.

Then, multiple quantum well active later 305 is formed by lowering the temperature of sapphire substrate 301 to 750° C., and second n-type GaN layer 306 is formed by raising the temperature of sapphire substrate 301 to 850° C. Thereafter, the temperature of sapphire substrate 301 is lowered to room temperature.

Even in such an example that second n-type GaN layer 306 is formed by setting a temperature of sapphire substrate 301 to a low temperature around 850° C. after multiple quantum well active later 305 is formed, higher resistance and significant deterioration in crystallinity of second n-type GaN layer 306 can be suppressed because second n-type GaN layer 306 is an n-type nitride semiconductor layer. Further, since second n-type GaN layer 306 can be formed at a temperature lower than in a conventional construction as shown in FIG. 11 where the p-type nitride semiconductor layer is formed on multiple quantum well active later 305, thermal damage to multiple quantum well active later 305 can be mitigated.

Thereafter, second n electrode 308 is formed on second n-type GaN layer 306 with EB (Electron Beam) vapor deposition. Here, second n electrode 308 is patterned as follows. Initially, after a photoresist is formed on the entire surface of second n-type GaN layer 306, an opening portion is provided in a shape of second n electrode 308 in that photoresist using general photolithography technique and etching technique. Then, second n electrode 308 is formed with EB vapor deposition so as to cover the entire surface of the photoresist and thereafter the photoresist is removed by lift-off, so that second n electrode 308 patterned in a prescribed shape is formed on second n-type GaN layer 306.

Then, a mask for vapor phase etching is formed on second n-type GaN layer 306, and by using ICP (Inductively Coupled Plasma) etching, etching is performed in a direction of thickness as far as the inside of first n-type GaN layer 302.

Then, with EB vapor deposition and sputtering, first n electrode 307 is formed on the exposed surface of first n-type GaN layer 302. Here, first n electrode 307 is patterned as second n electrode 308 is patterned.

Then, a thickness of sapphire substrate 301 after formation of first n electrode 307 above is decreased to approximately 100 μm by general grinding and polishing, and thereafter scribing with a diamond needle is performed to divide the substrate in chips each having a surface of 350 μm-square. The nitride semiconductor light-emitting diode device according to Example 1 is thus obtained.

Though the p-type nitride semiconductor layer doped with magnesium does not exhibit p-type electric conduction unless it is formed at a high temperature not lower than 1000° C., the n-type nitride semiconductor layer doped with silicon exhibits n-type electric conduction even at a low temperature lower than 1000° C. Therefore, second n-type GaN layer 306 can be formed even at a low temperature around 800° C. by optimizing a formation condition.

In addition, in the nitride semiconductor light-emitting diode device according to Example 1, since a positive voltage is applied to first n electrode 307 and a negative voltage is applied to second n electrode 308, first n electrode 307 serves as a positive electrode (an anode electrode) and second n electrode 308 serves as a negative electrode (a cathode electrode). By thus applying a voltage to the nitride semiconductor light-emitting diode device according to Example 1, light is emitted from multiple quantum well active later 305.

Meanwhile, a nitride semiconductor light-emitting diode device having a construction shown in a schematic cross-sectional view in FIG. 7 is fabricated as a Comparative Example. Here, the nitride semiconductor light-emitting diode device according to Comparative Example is constructed similarly to the nitride semiconductor light-emitting diode device according to Example 1, except that, instead of AN intermediate layer 303, a silicon-highly-doped layer 701 having a thickness of 10 nm and carrier density of 3.4×10¹⁹ cm⁻³ is formed in an upper portion of first n-type GaN layer 302, a magnesium-highly-doped layer 702 having a thickness of 10 nm and carrier density of 3×10¹⁸ cm⁻³ is formed in a lower portion of p-type GaN layer 304 as shown in the schematic cross-sectional view in FIG. 9, and a tunnel junction layer 703 having a tunnel junction formed by joint therebetween is formed.

In the nitride semiconductor light-emitting diode device according to Example 1, a drive voltage for drive by injecting a current of 20 mA is 4.6 V. On the other hand, a drive voltage for drive by injecting a current of 20 mA in the nitride semiconductor light-emitting diode device according to Comparative Example is approximately 7.5 V. Therefore, the nitride semiconductor light-emitting diode device according to Example 1 can achieve lowering in the drive voltage for drive by injecting a current of 20 mA by approximately 3 V as compared with the nitride semiconductor light-emitting diode device according to Comparative Example.

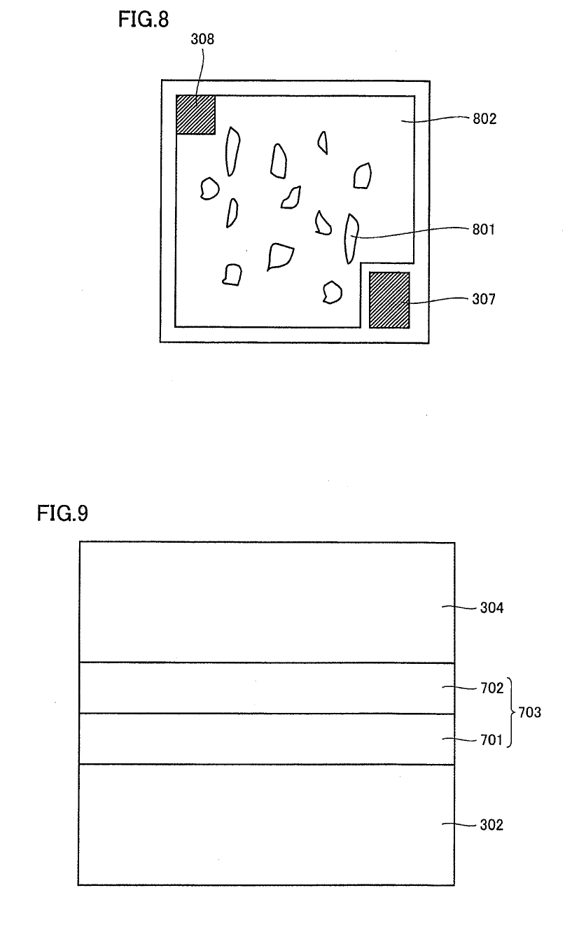

In addition, as a result of observation of a light emission pattern of the nitride semiconductor light-emitting diode device according to Example 1 and the nitride semiconductor light-emitting diode device according to Comparative Example with an optical microscope, it can be seen that, in the nitride semiconductor light-emitting diode device according to Comparative Example, a region 801 high in light emission intensity and a region 802 low in light emission intensity are present in a mixed manner as shown in FIG. 8, variation in light emission intensity is great, and current injection is not uniform.

On the other hand, in the nitride semiconductor light-emitting diode device according to Example 1, variation in light emission intensity as in the nitride semiconductor light-emitting diode device according to Comparative Example is hardly observed.

Further, in the nitride semiconductor light-emitting diode device according to Comparative Example, light emission intensity is different by approximately eight times between region 801 high in light emission intensity and region 802 low in light emission intensity, whereas in the nitride semiconductor light-emitting diode device according to Example 1, light emission intensity is suppressed to approximately three times between a region high in light emission intensity and a region low in light emission intensity.

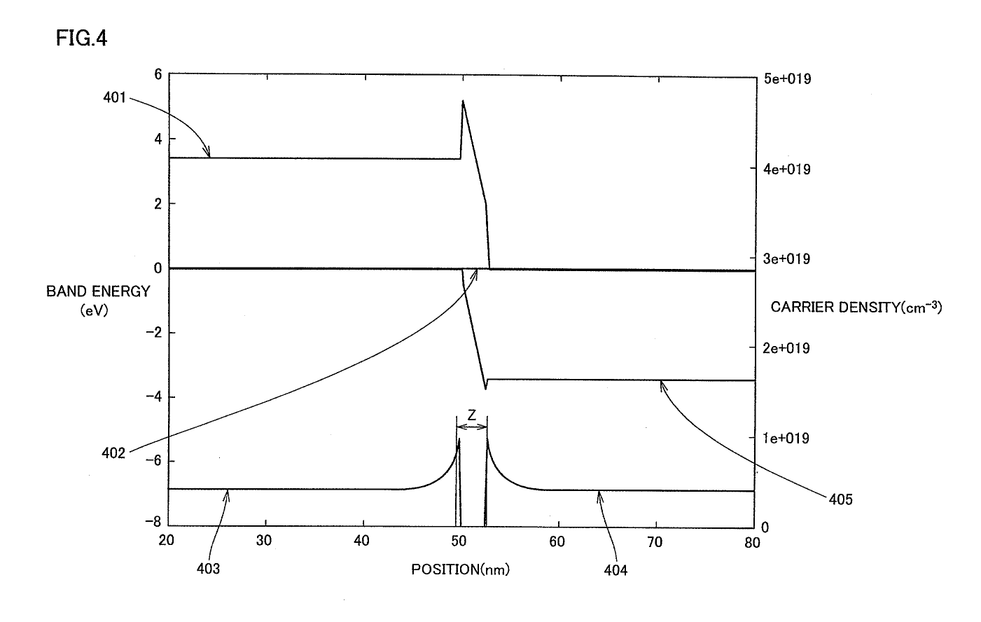

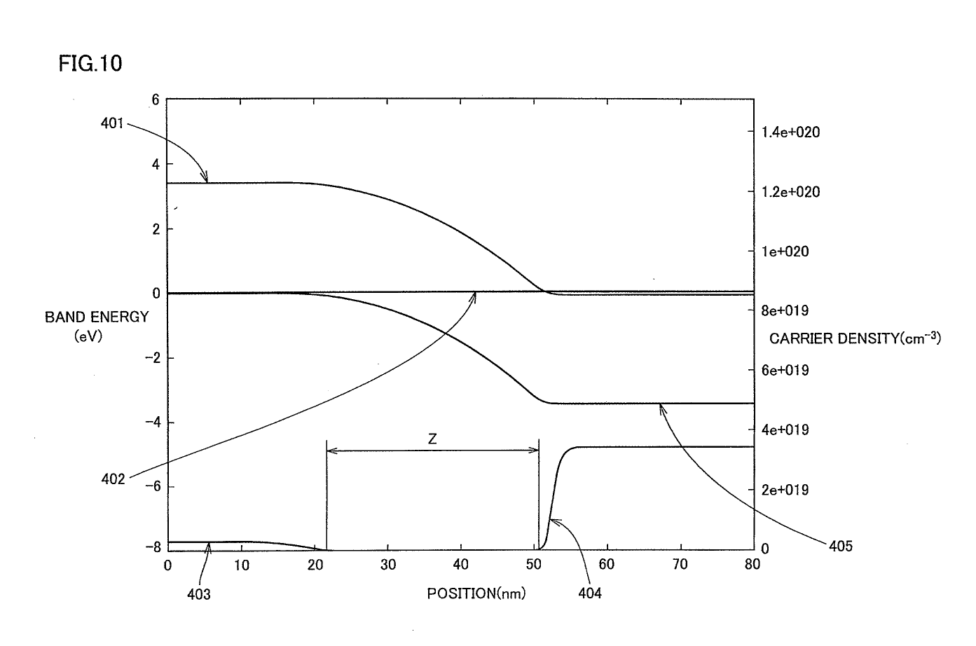

In addition, FIG. 4 shows a theoretical calculation result of a band energy diagram in the vicinity of AlN intermediate layer 303 of the nitride semiconductor light-emitting diode device according to Example 1, and FIG. 10 shows a theoretical calculation result of a band energy diagram in the vicinity of tunnel junction layer 703 of the nitride semiconductor light-emitting diode device according to Comparative Example.

In FIGS. 4 and 10, the abscissa represents a position (nm) in a direction of thickness and the ordinate represents band energy (eV) and carrier density (cm⁻³). It is noted that a position of 50 (nm) on the abscissa in FIG. 4 indicates a position of the interface between AlN intermediate layer 303 and p-type GaN layer 304, and a greater numeric value on the abscissa in FIG. 4 indicates the side of first n-type GaN layer 302 and a smaller numeric value on the abscissa in FIG. 4 indicates the side of p-type GaN layer 304. In addition, a position of 50 (nm) on the abscissa in FIG. 10 indicates a position of the interface between first n-type GaN layer 302 and silicon-highly-doped layer 701, and a greater numeric value on the abscissa in FIG. 10 indicates the side of first n-type GaN layer 302 and a smaller numeric value on the abscissa in FIG. 10 indicates the side of p-type GaN layer 304.

In FIGS. 4 and 10, band energy 401 in a conduction band and band energy 405 in a valence band are joined to each other such that they are identical in Fermi energy 402, a region where carrier density is not shown between a region where carrier density 403 of a p-type impurity is shown and a region where carrier density 404 of an n-type impurity is shown is a depletion layer where no carrier is present, and a width of the depletion layer is shown with z. Smaller width z of this depletion layer facilitates flow of a tunneling current.

As can be seen based on comparison of width z of the depletion layer between FIGS. 4 and 10, width z of the depletion layer is approximately 2.5 nm in the nitride semiconductor light-emitting diode device according to Example 1, whereas width z of the depletion layer is approximately 30 nm in the nitride semiconductor light-emitting diode device according to Comparative Example. Therefore, a width of the depletion layer in the nitride semiconductor light-emitting diode device according to Example 1 is approximately 1/10 that of the nitride semiconductor light-emitting diode device according to Comparative Example, and thus it is considered that a good tunneling current flows in the nitride semiconductor light-emitting diode device according to Example 1, which leads to lowering in a drive voltage.

Namely, in the nitride semiconductor light-emitting diode device according to Example 1, a lattice constant of AlN forming AlN intermediate layer 303 is smaller than a lattice constant of GaN forming first n-type GaN layer 302 and p-type GaN layer 304. Therefore, lattice strain due to lattice unmatch is caused by this difference in lattice constant, spontaneous polarization due to piezo electric field occurs along the C axis direction, and the C plane of AN intermediate layer 303 exhibits different characteristics between the +C axis side and the −C axis side. AlN intermediate layer 303 thus has the polar plane. Then, it is considered that a width of the depletion layer could be narrowed because a band is bent in AlN intermediate layer 303 having the polar plane.

In addition, the reason why variation in light emission intensity was hardly observed in the nitride semiconductor light-emitting diode device according to Example 1 may be because a voltage across first n-type GaN layer 302 and p-type GaN layer 304 was lowered by insertion of AlN intermediate layer 303 and resistance between these layers lowered, and thus a current could uniformly be injected.

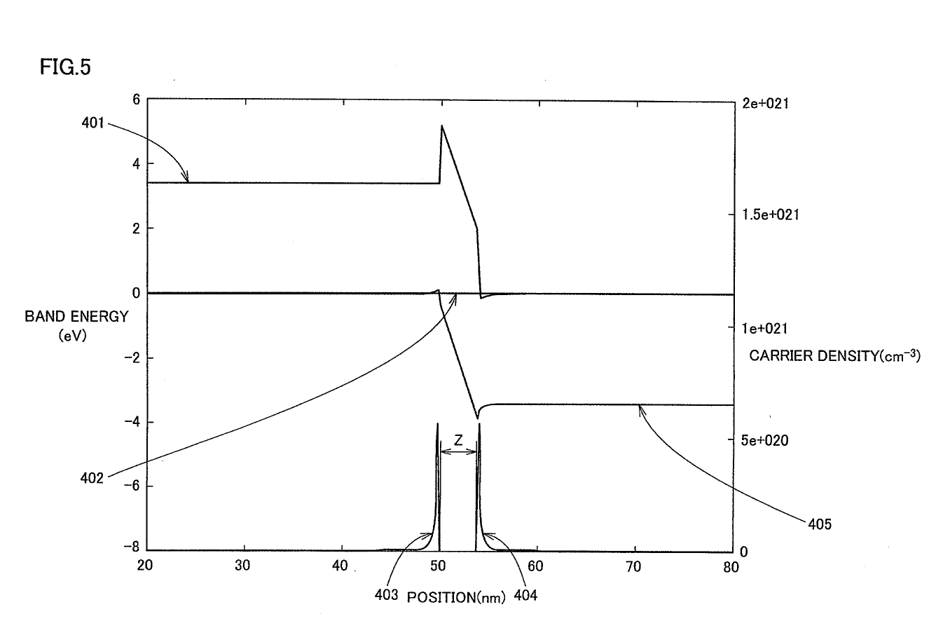

FIG. 5 shows a theoretical calculation result of a band energy diagram in the vicinity of AlN intermediate layer 303, when a thickness of AN intermediate layer 303 of the nitride semiconductor light-emitting diode device according to Example 1 is changed to 4 nm. In this case, width z of the depletion layer is approximately 4 nm, which is approximately 1/7 of a width of the depletion layer in the nitride semiconductor light-emitting diode device according to Comparative Example. Therefore, it can be seen that an effect of the present invention that a good tunneling current flows and a drive voltage is lowered is obtained even when a thickness of AlN intermediate layer 303 is changed to 4 nm. Description in connection with FIG. 5 is otherwise the same as that in connection with FIG. 4.

It is noted that the effect as in the present example is not limited to a case where intermediate layer 303 is composed of AlN, and it can be achieved also in a case where intermediate layer 303 is composed of AlₓGa₁₋ₓN (0<x≦1).

In addition, an effect the same as in the present example is obtained also when a temperature of sapphire substrate 301 is set to approximately 500° C. and first n-type GaN layer 302 is formed after a GaN buffer layer is formed on the (0001) plane which is the C plane of sapphire substrate 301.

Moreover, an effect the same as in the present example is obtained also when an n-type nitride semiconductor substrate is used instead of sapphire substrate 301, intermediate layer 303 is directly formed on the polar plane or the semipolar plane of the n-type nitride semiconductor substrate, and p-type GaN layer 304 is formed on that intermediate layer 303, with change to the vertical electrode structure as shown in FIG. 2 being made.

Further, an effect the same as above is obtained also when a mixed crystal containing Al is used for multiple quantum well active later 305, and furthermore, when the In composition ratio in the well layer forming multiple quantum well active later 305 is varied as appropriate to change a light emission wavelength as well, an effect the same as in the present example is obtained.

In the present invention, unlike a conventional general structure, the active layer is formed on the p-type nitride semiconductor layer. Multiple quantum well active later 305 is formed by layering a non-doped GaN layer having a thickness of 60 nm, a non-doped In_{0.02}Ga_{0.98}N barrier layer having a thickness of 8 nm and a non-doped In_{0.2}Ga_{0.8}N well layer having a thickness of 4 nm in this order, from the side of p-type Al_{0.1}Ga_{0.9}N carrier blocking layer 309. When the well layer which is the active layer is directly formed on the p-type nitride semiconductor layer, light emission intensity may be lowered due to diffusion of Mg which is a p-type dopant into the active layer. Therefore, a gap not smaller than 5 nm is preferably provided between the p-type nitride semiconductor layer and the well layer which is the active layer. It is noted that a non-doped nitride semiconductor layer is preferably formed in the gap as in the present example.

### Example 2

A nitride semiconductor light-emitting diode device is fabricated as in Example 1, except that a composition of intermediate layer 303 of the nitride semiconductor light-emitting diode device according to Example 1 is changed to Al_{0.3}Ga_{0.7}N and a thickness of intermediate layer 303 is changed to 20 nm.

The nitride semiconductor light-emitting diode device according to Example 2 thus fabricated can also achieve suppressed variation in light emission intensity and also lowering in a drive voltage, as compared with the nitride semiconductor light-emitting diode device according to Comparative Example, as in the case of nitride semiconductor light-emitting diode device according to Example 1 above.

### Example 3

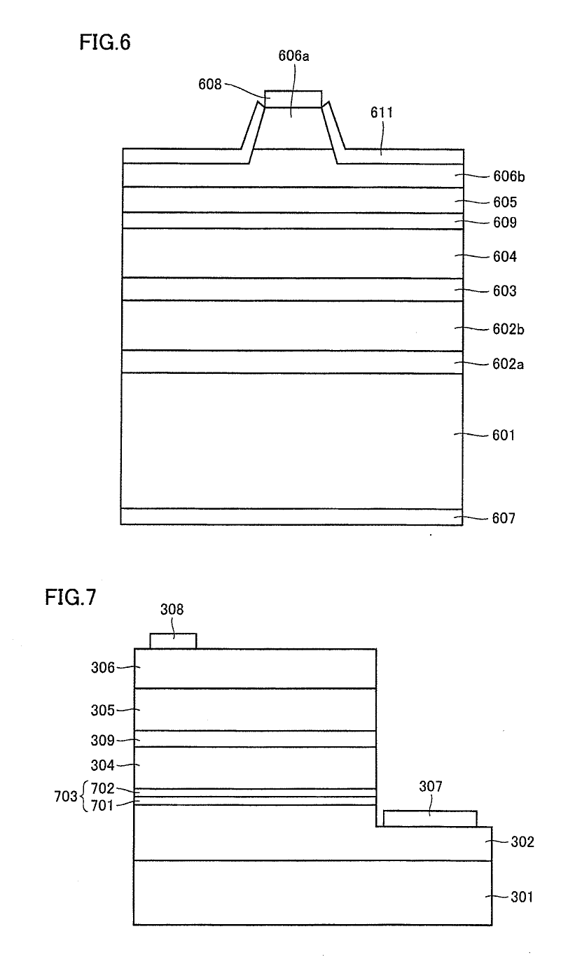

FIG. 6 shows a schematic cross-sectional view of a nitride semiconductor laser device according to Example 3 representing one example of the nitride semiconductor light-emitting device according to the present invention. Here, the nitride semiconductor laser device according to Example 3 has such a structure that a first n-type Al_{0.05}Ga_{0.95}N cladding layer 602a having a thickness of 2.5 μm, a first n-type GaN guide layer 602b having a thickness of 0.1 μm, an Al_{0.8}Ga_{0.2}N intermediate layer 603 having a thickness of 2.5 nm, a p-type GaN guide layer 604 having a thickness of 0.2 μm, a p-type Al_{0.1}Ga_{0.9}N carrier blocking layer 609 having a thickness of 0.01 μm, a multiple quantum well active later 605 having a thickness of 0.144 μm, a second n-type GaN guide layer 606b having a thickness of 0.2 μm, and a second n-type Al_{0.05}Ga_{0.95}N cladding layer 606a having a thickness of 0.6 μm are stacked in this order on an n-type GaN substrate 601 having a thickness of 400 μm.

In addition, as a part of second n-type Al_{0.05}Ga_{0.95}N cladding layer 606a and a part of second n-type GaN guide layer 606b are removed, a ridge stripe portion extending in a direction of a length of a resonator (a stripe width of the ridge stripe portion: 1.2 to 2.4 μm) is formed and a side surface of the ridge stripe portion and a surface of second n-type Al_{0.05}Ga_{0.95}N cladding layer 606a are covered with an insulating film 611.

Moreover, a first n electrode 607 is formed on a back surface of n-type GaN substrate 601 and a second n electrode 608 is formed on second n-type Al_{0.05}Ga_{0.95}N cladding layer 606a.

Here, multiple quantum well active later 605 is formed as its mixed crystal ratio is adjusted such that a laser beam oscillating from the nitride semiconductor laser device according to Example 3 has a wavelength of 500 nm, and specifically, it has such a construction that a non-doped GaN layer having a thickness of 60 nm, a stack in which a non-doped In_{0.02}Ga_{0.98}N barrier layer having a thickness of 8 nm and a non-doped In_{0.2}Ga_{0.8}N well layer having a thickness of 4 nm are alternately stacked two times, and a non-doped GaN layer having a thickness of 60 nm are stacked in this order from the side of p-type Al_{0.1}Ga_{0.9}N carrier blocking layer 609.

In addition, first n electrode 607 is formed in contact with n-type GaN substrate 601, and it has such a construction that a hafnium film (a thickness of 30 nm), an aluminum film (a thickness of 200 nm), a molybdenum film (a thickness of 30 nm), a platinum film (a thickness of 50 nm), and a gold film (a thickness of 200 nm) are stacked in this order from the side of n-type GaN substrate 601.

Second n electrode 608 is identical in structure to first n electrode 607. In addition, insulating film 611 is constructed such that a silicon oxide layer having a thickness of 200 nm and a titanium oxide layer having a thickness of 50 nm are stacked in this order.

In addition, each of first n-type Al_{0.05}Ga_{0.95}N cladding layer 602a, first n-type GaN guide layer 602b, second n-type Al_{0.05}Ga_{0.95}N cladding layer 606a, and second n-type GaN guide layer 606b has carrier density of approximately 1×10¹⁸ cm⁻³. Further, p-type GaN guide layer 604 has carrier density of approximately 4×10¹⁷ cm⁻³. Al_{0.8}Ga_{0.2}N intermediate layer 603 is not doped with a p-type impurity and an n-type impurity intentionally.

The nitride semiconductor laser device according to Example 3 having the construction above is manufactured as follows.

Initially, using an MOCVD film deposition apparatus, first n-type Al_{0.05}Ga_{0.95}N cladding layer 602a, first n-type GaN guide layer 602b, Al_{0.8}Ga_{0.2}N intermediate layer 603, p-type GaN guide layer 604, p-type Al_{0.1}Ga_{0.9}N carrier blocking layer 609, multiple quantum well active later 605, second n-type GaN guide layer 606b, and second n-type Al_{0.05}Ga_{0.95}N cladding layer 606a are epitaxially grown in this order with MOCVD on the (0001) plane which is the C plane of n-type GaN substrate 601 having a surface having a diameter of 2 inches and a thickness of 400 μm. Here, ammonia is used as a nitrogen source, TMG is used as a gallium source, TMI is used as an indium source, TMA is used as an aluminum source, Cp2Mg is used as a source of magnesium which is a p-type impurity, and silane is used as a source of silicon which is an n-type impurity.

Here, first n-type Al_{0.05}Ga_{0.95}N cladding layer 602a to the non-doped GaN layer on the side closer to n-type GaN substrate 601 in multiple quantum well active later 605 are formed by setting a temperature of n-type GaN substrate 601 to 1125° C., and thereafter remaining portions of multiple quantum well active later 605 are formed by lowering a temperature of n-type GaN substrate 601 to 750° C. Then, second n-type GaN guide layer 606b and second n-type Al_{0.05}Ga_{0.95}N cladding layer 606a are formed by raising the temperature of n-type GaN substrate 601 to 850° C. Thereafter, the temperature of n-type GaN substrate 601 is lowered to room temperature.

Even in such an example that second n-type GaN guide layer 606b and second n-type Al_{0.05}Ga_{0.95}N cladding layer 606a are formed by setting a temperature of n-type GaN substrate 601 to a low temperature around 850° C. after multiple quantum well active later 605 is formed, higher resistance and significant deterioration in crystallinity of second n-type GaN guide layer 606b and second n-type Al_{0.05}Ga_{0.95}N cladding layer 606a can be suppressed because second n-type GaN guide layer 606b and second n-type Al_{0.05}Ga_{0.95}N cladding layer 606a are each an n-type nitride semiconductor layer. Further, since second n-type GaN guide layer 606b and second n-type Al_{0.05}Ga_{0.95}N cladding layer 606a can be formed on multiple quantum well active later 605 at a temperature lower than in a conventional construction as shown in FIG. 11 where the p-type nitride semiconductor layer is formed, thermal damage to multiple quantum well active later 605 can be mitigated.

Thereafter, second n electrode 608 is formed on second n-type Al_{0.05}Ga_{0.95}N cladding layer 606a with EB (Electron Beam) vapor deposition. Then, after a photoresist is formed on the entire surface of second n electrode 608, an opening portion is provided in a region in that photoresist where a ridge stripe portion is not formed, by using general photolithography technique and etching technique. Thereafter, by using ICP etching, etching is performed in a direction of thickness as far as the inside of second n-type GaN guide layer 606b. Then, insulating film 611 is formed by stacking a silicon oxide layer and a titanium oxide layer in this order on the entire surface of the photoresist, with EB vapor deposition and sputtering. Thereafter, by removing the photoresist by lift-off, second n electrode 608 is formed on second n-type Al_{0.95}Ga_{0.95}N cladding layer 606a and insulating film 611 patterned in a prescribed shape is formed.

Then, first n electrode 607 is formed on the back surface of n-type GaN substrate 601 with EB vapor deposition.

Then, a thickness of n-type GaN substrate 601 after formation of first n electrode 607 above is decreased to approximately 100 μm by general grinding and polishing, and thereafter scribing with a diamond needle is performed to cleave in a bar shape. Then, an end surface coating film implemented by a dielectric film expressed with a formula AlOₐN₁₋ₐ(0≦a) is formed to a thickness of approximately 30 nm on an end surface of a resonator exposed by this cleaving. Here, reflectance at the end surface of the resonator on the light emission side is set to 10% and reflectance at the end surface of the resonator on the light reflection side is set to 90%. The nitride semiconductor laser device according to Example 3 is thus obtained.

Meanwhile, a nitride semiconductor laser device according to a Comparative Example having a construction the same as that of the nitride semiconductor laser device according to Example 3 is fabricated as Comparative Example except that, instead of Al_{0.8}Ga_{0.2}N intermediate layer 603, a silicon-highly-doped layer having a thickness of 50 nm and carrier density of 3.4×10¹⁹ cm⁻³ is formed in an upper portion of first n-type GaN guide layer 602b, a magnesium-highly-doped layer having a thickness of 50 nm and carrier density of 3×10¹⁸ cm⁻³ is formed in a lower portion of p-type GaN guide layer 604, and a tunnel junction layer having a tunnel junction formed by joint therebetween is formed.

In the nitride semiconductor laser device according to Example 3, a drive voltage for drive by injecting a current of 20 mA is 6.2 V. On the other hand, a drive voltage for drive by injecting a current of 20 mA in the nitride semiconductor laser device according to Comparative Example is approximately 9.0 V. Therefore, the nitride semiconductor laser device according to Example 3 can achieve lowering in the drive voltage for drive by injecting a current of 20 mA by approximately 3 V as compared with the nitride semiconductor laser device according to Comparative Example.

In the nitride semiconductor laser device according to Example 3, after multiple quantum well active later 605 is formed, only n-type nitride semiconductor layers such as second n-type GaN guide layer 606b and second n-type Al_{0.05}Ga_{0.95}N cladding layer 606a are formed and a p-type nitride semiconductor layer is not formed. Therefore, the construction of the nitride semiconductor laser device according to Example 3 can be concluded as an excellent construction when the In composition ratio in the well layer in multiple quantum well active later 605 is not lower than 0.15 and in particular not lower than 0.2.

In addition, in the conventional nitride semiconductor laser device, since the ridge stripe portion has been formed of a p-type nitride semiconductor layer having high resistance, a drive voltage has been high. The nitride semiconductor laser device according to Example 3, however, is preferred in that the ridge stripe portion is formed of an n-type nitride semiconductor layer lower in resistance than the p-type nitride semiconductor layer and thus a drive voltage can be suppressed to be low as compared with the conventional nitride semiconductor laser device.

Moreover, in the conventional nitride semiconductor laser device, a p electrode in contact with the p-type nitride semiconductor layer and an n electrode in contact with the n-type nitride semiconductor layer should be formed. In the nitride semiconductor laser device according to Example 3, however, only an n electrode can be used and hence contact resistance between the electrode and the nitride semiconductor can be lowered as compared with the conventional nitride semiconductor laser device.

Further, in the nitride semiconductor laser device according to Example 3, first n electrode 607 and second n electrode 608 may be identical to each other or different from each other. If they are identical to each other, productivity is improved because it is not necessary to change a condition for formation or the like. In addition, since the same material can be used, manufacturing cost can be reduced. It is noted that such a construction as a stack of a titanium layer and an aluminum layer can also be employed for first n electrode 607 and second n electrode 608.

In the nitride semiconductor laser device according to Example 3, an oxide film (for example, at least one of a silicon oxide film, an aluminum oxide film, a zirconium oxide film, a tantalum oxide film, a titanium oxide film, a niobium oxide film, and the like), a nitride film (for example, at least one of a silicon nitride film, an aluminum nitride film, and the like), an oxynitride film (for example, at least one of a silicon oxynitride film, an aluminum oxynitride film, and the like), or the like may be formed on the end surface coating film implemented by the dielectric film expressed with the formula AlOₐN (0≦a).

In addition, in the nitride semiconductor laser device according to Example 3, by changing as appropriate the construction of multiple quantum well active later 605, for example, the construction may be such that a laser beam having a wavelength from 380 nm to 550 nm oscillates.

Moreover, in the nitride semiconductor laser device according to Example 3, instead of n-type GaN substrate 601, an n-type AlGaN substrate, an n-type AlN substrate, an n-type InGaN substrate, or the like may be employed.

Further, the nitride semiconductor laser device according to Example 3 may be implemented by a nitride semiconductor laser device of a broad area type used for illumination applications and the like, for example, by setting a width of the ridge stripe portion to approximately 2 μm to 100 μm.

### Example 4

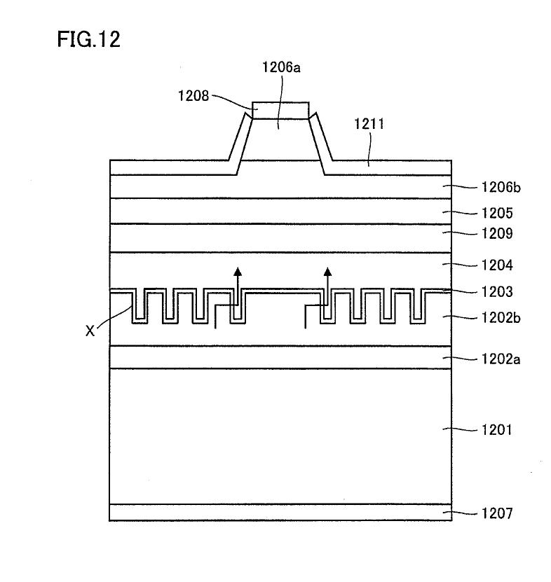

FIG. 12 shows a schematic cross-sectional view of a nitride semiconductor laser device according to Example 4 representing one example of the nitride semiconductor light-emitting device according to the present invention. Here, the nitride semiconductor laser device according to Example 4 is different from the nitride semiconductor laser device according to Example 3 in that the nitride semiconductor laser device is fabricated by employing a substrate having a nonpolar plane and forming an intermediate layer having a polar plane.

The nitride semiconductor laser device according to Example 4 has such a construction that a first n-type Al_{0.05}Ga_{0.95}N cladding layer 1202a having a thickness of 2.5 μm, a first n-type GaN guide layer 1202b having a thickness of 0.1 μm, an AlN intermediate layer 1203 having a thickness of 2.5 nm, a p-type GaN guide layer 1204 having a thickness of 0.2 μm, a p-type Al_{0.1}Ga_{0.9}N carrier blocking layer 1209 having a thickness of 0.01 μm, a multiple quantum well active later 1205 having a thickness of 0.144 m, a second n-type GaN guide layer 1206b having a thickness of 0.2 μm, and a second n-type Al_{0.05}Ga_{0.95}N cladding layer 1206a having a thickness of 0.6 μm are stacked in this order on the m plane of an n-type GaN substrate 1201 having a thickness of 400 μm.

In addition, as a part of second n-type Al_{0.05}Ga_{0.95}N cladding layer 1206a and a part of second n-type GaN guide layer 1206b are removed, a ridge stripe portion extending in a direction of a length of a resonator (a stripe width of the ridge stripe portion: 1.2 to 2.4 μm) is formed and a side surface of the ridge stripe portion and a surface of second n-type Al_{0.05}Ga_{0.95}N cladding layer 1206a are covered with an insulating film 1211.

Moreover, a first n electrode 1207 is formed on a back surface of n-type GaN substrate 1201 and a second n electrode 1208 is formed on second n-type Al_{0.05}Ga_{0.95}N cladding layer 1206a. Here, first n electrode 1207 is an anode electrode and a positive bias voltage is applied thereto, and second n electrode 1208 is a cathode electrode and a negative bias voltage is applied thereto.

Here, multiple quantum well active later 1205 is formed as its mixed crystal ratio is adjusted such that a laser beam oscillating from the nitride semiconductor laser device according to Example 4 has a wavelength of 520 nm, and specifically, it has such a construction that a non-doped GaN layer having a thickness of 60 nm, a stack in which a non-doped In_{0.02}Ga_{0.98}N barrier layer having a thickness of 8 nm and a non-doped In_{0.2}Ga_{0.8}N well layer having a thickness of 4 nm are alternately stacked two times, and a non-doped GaN layer having a thickness of 60 nm are stacked in this order from the side of p-type Al_{0.1}Ga_{0.9}N carrier blocking layer 1209.

In addition, first n electrode 1207 is formed in contact with n-type GaN substrate 1201, and it has such a construction that a hafnium film (a thickness of 30 nm), an aluminum film (a thickness of 200 nm), a molybdenum film (a thickness of 30 nm), a platinum film (a thickness of 50 nm), and a gold film (a thickness of 200 nm) are stacked in this order from the side of n-type GaN substrate 1201.

Second n electrode 1208 is identical in structure to first n electrode 1207. In addition, insulating film 1211 is constructed such that a silicon oxide layer having a thickness of 200 nm and a titanium oxide layer having a thickness of 50 nm are stacked in this order.

In addition, each of first n-type Al_{0.05}Ga_{0.95}N cladding layer 1202a, first n-type GaN guide layer 1202b, second n-type Al_{0.05}Ga_{0.95}N cladding layer 1206a, and second n-type GaN guide layer 1206b has carrier density of approximately 1×10¹⁸ cm⁻³. Further, p-type GaN guide layer 1204 has carrier density of approximately 4×10¹⁷ cm⁻³. Al_{0.8}Ga_{0.2}N intermediate layer 1203 is not doped with a p-type impurity and an n-type impurity intentionally.

The nitride semiconductor laser device according to Example 4 having the construction above is manufactured as follows.

Initially, using an MOCVD film deposition apparatus, first n-type Al_{0.05}Ga_{0.95}N cladding layer 1202a and first n-type GaN guide layer 1202b are grown on the (1-100) plane which is the non-polar m plane of n-type GaN substrate 1201 having a surface having a diameter of 2 inches and a thickness of 400 μm.

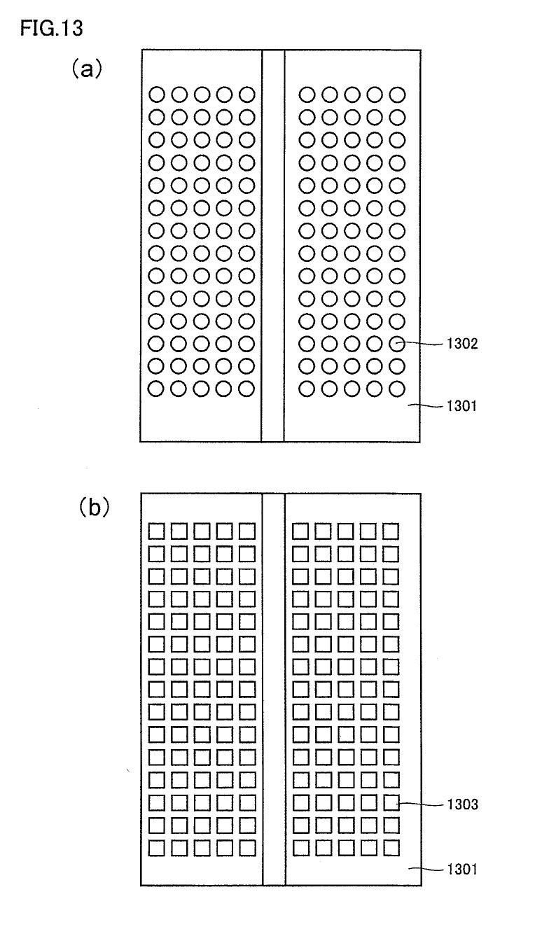

Then, n-type GaN substrate 1201 on which first n-type GaN guide layer 1202b has grown is once taken out of the MOCVD film deposition apparatus, and for example, a resist pattern 1301 having an annular opening portion 1302 as shown in the schematic plan view in FIG. 13(a) or a resist pattern 1301 having a rectangular opening portion 1303 as shown in the schematic plan view in FIG. 13(b) is formed on the surface of first n-type GaN guide layer 1202b with a general photolithography process. Thereafter, a part of first n-type GaN guide layer 1202b is removed in a direction perpendicular to the surface of first n-type GaN guide layer 1202b in a shape of opening portion 1302 in resist pattern 1301 shown in FIG. 13(a) or opening portion 1303 in resist pattern 1301 shown in FIG. 13(b), to thereby form irregularities in the surface of first n-type GaN guide layer 1202b. It is noted that a shape of a removed portion of first n-type GaN guide layer 1202b is not limited to the annular shape and the rectangular shape above, and it may be in other shapes such as a triangular shape. In addition, a depth of the removed portion of first n-type GaN guide layer 1202b may be set, for example, approximately to 0.01 μm to 0.3 μm, so as to remove even a part of first n-type Al_{0.05}Ga_{0.95}N cladding layer 1202a. Moreover, a size of a surface of the removed portion can be set, for example, approximately to 0.1 μm to 5 μm. It is noted that a size of the surface of the removed portion refers to a diameter in the case of the annular shape, and refers to a length of a longest side in the case of a polygon such as a rectangle.

N-type GaN substrate 1201 after formation of the irregularities above is returned to the MOCVD film deposition apparatus, and AN intermediate layer 1203, p-type GaN guide layer 1204, p-type Al_{0.1}Ga_{0.9}N carrier blocking layer 1209, multiple quantum well active later 1205, second n-type GaN guide layer 1206b, and second n-type Al_{0.05}Ga_{0.95}N cladding layer 1206a are epitaxially grown in this order with MOCVD. Thereafter, through the process the same as in Example 3, the nitride semiconductor laser device according to Example 4 is obtained.

In the nitride semiconductor laser device according to Example 4, a drive voltage for drive by injecting a current of 20 mA is 6.8 V. On the other hand, a drive voltage for drive by injecting a current of 20 mA in the nitride semiconductor laser device according to Comparative Example above is approximately 9.0 V. Therefore, the nitride semiconductor laser device according to Example 4 can achieve lowering in the drive voltage for drive by injecting a current of 20 mA by 2 V or more, as compared with the nitride semiconductor laser device according to Comparative Example.

For example, in a case where the nitride semiconductor laser device having the construction shown in FIG. 12 is fabricated by using resist pattern 1301 shown in FIGS. 13(a) and 13(b), a polar plane instead of the m plane is formed on a side surface X of first n-type GaN guide layer 1202b. Thus, if AlN intermediate layer 1203 has the polar plane at an interface with first n-type GaN guide layer 1202b and at an interface with p-type GaN guide layer 1204, a tunneling current effectively flows by utilizing the polar plane (side surface) as shown with an arrow in FIG. 12.

### Example 5

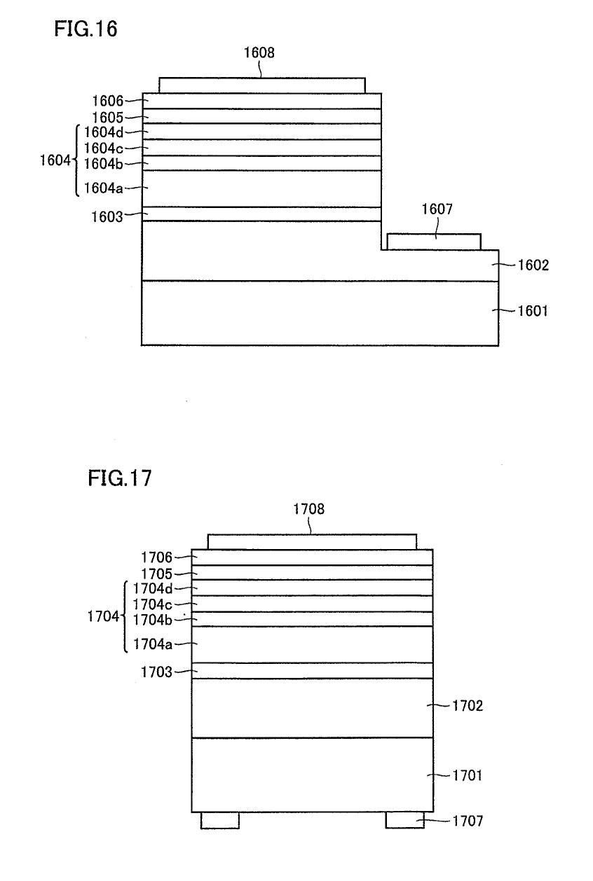

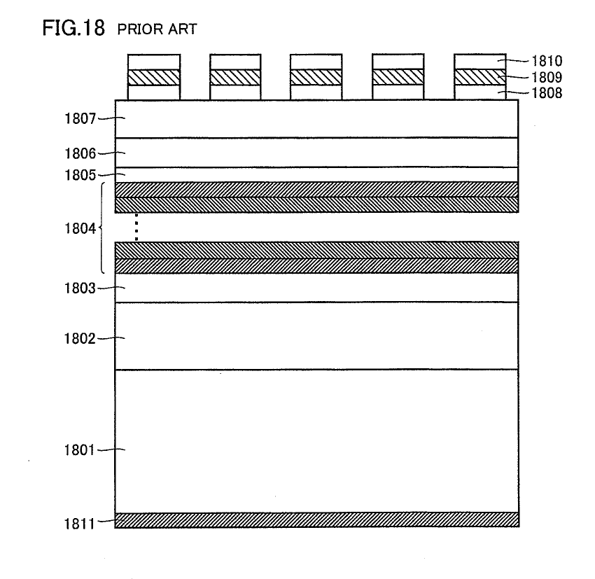

FIG. 16 shows a schematic cross-sectional view of a nitride semiconductor light-emitting diode device according to Example 5 representing one example of the semiconductor light-emitting device according to the present invention. Here, the nitride semiconductor light-emitting diode device according to Example 5 has such a construction that a first n-type GaN layer 1602 having a thickness of 5 μm, an AlN intermediate layer 1603 having a thickness of 2.5 nm, a second lower layer 1604, a multiple quantum well active later 1605, and a second n-type GaN layer 1606 having a thickness of 10 nm are stacked in this order on a sapphire substrate 1601 having a thickness of 150 μm, in which a first n electrode 1607 is formed on first n-type GaN layer 1602 and a second n electrode 1608 is formed on second n-type GaN layer 1606.

Here, second lower layer 1604 includes a p-type GaN layer 1604a having a thickness of 0.3 μm, a p-type Al_{0.1}Ga_{0.9}N carrier blocking layer 1604b having a thickness of 10 nm, a non-doped GaN layer 1604c having a thickness of 60 nm, and a non-doped In_{0.02}Ga_{0.98}N layer 1604d having a thickness of 8 nm that are successively stacked. It is noted that non-doped GaN layer 1604c and non-doped In_{0.02}Ga_{0.98}N layer 1604d on p-type Al_{0.1}Ga_{0.9}N carrier blocking layer 1604b play a role like a buffer layer for forming good multiple quantum well active later 1605 on p-type Al_{0.1}Ga_{0.9}N carrier blocking layer 1604b relatively small in lattice constant, and they also play a role to prevent diffusion of Mg from p-type Al_{0.1}Ga_{0.9}N carrier blocking layer 1604b to multiple quantum well active later 1605 because light emission efficiency may lower in the event that Mg diffuses into multiple quantum well active later 1605.

In addition, multiple quantum well active later 1605 has such a stack structure that an Si-doped InGaN well layer having a thickness of 4 nm, an Si-doped In_{0.02}Ga_{0.98}N barrier layer having a thickness of 8 nm, and an Si-doped InGaN well layer having a thickness of 4 nm are successively deposited.

First n electrode 1607 is formed on a partially exposed surface of first n-type GaN layer 1602, and first n electrode 1607 is formed in contact with the surface of first n-type GaN layer 1602. Here, first n electrode 1607 includes an Hf layer (a thickness of 30 nm), an Al layer (a thickness of 200 nm), an Mo layer (a thickness of 30 nm), a Pt layer (a thickness of 50 nm), and an Au layer (a thickness of 200 nm) stacked in this order from the side of first n-type GaN layer 1602. In addition, second n electrode 1608 is formed on the surface of second n-type GaN layer 1606, and second n electrode 1608 is formed in contact with the surface of second n-type GaN layer 1606. Here, second n electrode 1608 includes an Ag layer (a thickness of 30 nm), a Pt layer (a thickness of 50 nm), and an Au layer stacked in this order from the side of second n-type GaN layer 1606. Thus, surface plasmon polariton (SPP) is produced at the surface of the Ag layer in contact with second n-type GaN layer 1606 (an Ag interface).

The nitride semiconductor light-emitting diode device according to Example 5 having the construction above is manufactured as follows. Initially, using an MOCVD film deposition apparatus, first n-type GaN layer 1602 to second n-type GaN layer 1606 are successively epitaxially grown with MOCVD on the (0001) plane which is the C plane of sapphire substrate 1601 having a surface having a diameter of 2 inches and a thickness of 400 μm. Here, ammonia is used as a nitrogen source, TMG (trimethylgallium) is used as a gallium source, TMI (trimethylindium) is used as an indium source, TMA (trimethylaluminum) is used as an aluminum source, Cp2Mg (bis(cyclopentadienyl)magnesium) is used as a source of magnesium which is a p-type impurity, and silane is used as a source of silicon which is an n-type impurity.

It is noted that carrier density of each of first n-type GaN layer 1602 and second n-type GaN layer 1606 is approximately 1×10¹⁸ cm ⁻³. In addition, carrier density of p-type GaN layer 1604a is approximately 4×10¹⁷ cm⁻³. AlN intermediate layer 1603 is not doped with a p-type impurity and an n-type impurity intentionally.

First n-type GaN layer 1602 is formed by setting a temperature of sapphire substrate 1601 to 1125° C., and AlN intermediate layer 1603, p-type GaN layer 1604a and p-type Al_{0.1}Ga_{0.9}N carrier blocking layer 1604b are also successively formed by setting a temperature of sapphire substrate 1601 to 1125° C.

Then, non-doped GaN layer 1604c, non-doped In_{0.02}Ga_{0.98}N layer 1604d and multiple quantum well active later 1605 are formed by lowering the temperature of sapphire substrate 1601 to 750° C., and second n-type GaN layer 1606 is formed by raising the temperature of sapphire substrate 1601 to 850° C. Even in such an example that second n-type GaN layer 1606 is formed by setting a temperature of sapphire substrate 1601 to a relatively low temperature around 850° C. after multiple quantum well active later 1605 is formed, higher resistance and significant deterioration in crystallinity of second n-type GaN layer 1606 can be suppressed because second n-type GaN layer 1606 is an n-type nitride semiconductor layer. Even when second n-type GaN layer 1606 has a thickness, for example, as small as approximately 10 nm, good doping with an n-type impurity can be carried out.

If a p-type nitride semiconductor layer is provided on multiple quantum well active later 1605, it is difficult to grow a nitride semiconductor crystal for providing p-type conductivity at a low temperature around 850° C. In contrast, if a temperature of sapphire substrate 1601 is raised in order to provide p-type conductivity, the Si-doped InGaN well layer in multiple quantum well active later 1605 deteriorates due to temperature increase. In this case, if restriction on a thickness of a layer provided on multiple quantum well active later 1605 is not imposed, an evaporation prevention layer for preventing evaporation can be provided on multiple quantum well active later 1605, however, under the condition of the present invention that only a thickness at most around 40 nm is tolerated, it is difficult to provide an evaporation prevention layer on multiple quantum well active later 1605.

In addition, though the p-type nitride semiconductor layer doped with Mg does not exhibit p-type conductivity unless it is formed at a high temperature not lower than 1000° C., the n-type nitride semiconductor layer doped with Si exhibits n-type conductivity even when it is formed at a low temperature lower than 1000° C. Therefore, second n-type GaN layer 1606 can be formed by optimizing a formation condition, even if a temperature of sapphire substrate 1601 is set to a low temperature around 800° C.

Thereafter, second n electrode 1608 is formed on second n-type GaN layer 1606 with EB (Electron Beam) vapor deposition. In succession, a mask for vapor phase etching is formed on second n-type GaN layer 1606 and second n electrode 1608, and etching is performed in a direction of thickness as far as the inside of first n-type GaN layer 1602 by using ICP (Inductively Coupled Plasma) etching. Then, with EB vapor deposition and sputtering, first n electrode 1607 is formed on the partially exposed surface of first n-type GaN layer 1602.

Then, a thickness of sapphire substrate 1601 after formation of first n electrode 1607 above is decreased to approximately 150 μm by general grinding and polishing, and thereafter scribing is performed to divide the substrate in chips each having a surface of 350 μm-square. The nitride semiconductor light-emitting diode device according to Example 5 is thus obtained.

In the nitride semiconductor light-emitting diode device according to this Example 5, by applying a voltage with first n electrode 1607 serving as an anode electrode and second n electrode 1608 serving as a cathode electrode, blue light (having a peak wavelength of approximately 460 nm) is emitted from multiple quantum well active later 1605. In addition, a drive voltage for causing the nitride semiconductor light-emitting diode device according to Example 5 to emit light by injecting a current of 20 mA is 4 V, and the emitted light is extracted to the outside through sapphire substrate 1601 of the nitride semiconductor light-emitting diode device according to Example 5 and a side surface of the nitride semiconductor light-emitting diode device according to Example 5. Estimating internal quantum efficiency of light emission from the nitride semiconductor light-emitting diode device according to Example 5, it was 90% or higher when a current of 20 mA was injected for driving and an extremely high value was achieved.

This is considered as follows. In the nitride semiconductor light-emitting diode device according to Example 5, light emitted from multiple quantum well active later 1605 and surface plasmon at the Ag interface of second n electrode 1608 were efficiently coupled to each other and consequently a light emission enhancement effect for light from multiple quantum well active later 1605 (increase in spontaneous emission rate) could be realized to such an extent that nonradiative recombination does not give rise to a problem at room temperature.

### Example 6

A nitride semiconductor light-emitting diode device according to Example 6 is the same as that in Example 5 except that a peak light emission wavelength of light emitted from multiple quantum well active later 1605 of the nitride semiconductor light-emitting diode device according to Example 5 was changed to 550 nm and a metal layer on the side of second n-type GaN layer 1606 in second n electrode 1608 was changed from the Ag layer to the Au layer.

Estimating internal quantum efficiency of light emission from the nitride semiconductor light-emitting diode device according to Example 6, it was 50% or higher when a current of 20 mA was injected in the nitride semiconductor light-emitting diode device according to Example 6 for driving the same, and a high value was achieved.

In view of the fact that it has been known that most efficient light emission is likely to be obtained at a wavelength around 400 nm when a nitride semiconductor active layer is used and conventional internal quantum efficiency in connection with light emission in a green region around a wavelength of 550 nm lowers to approximately ¼, the internal quantum efficiency of 50% is a very good value. Therefore, it is considered that light emitted from the active layer and surface plasmon at the Au interface were efficiently coupled to each other also in the nitride semiconductor light-emitting diode device according to Example 6, and consequently a light emission enhancement effect for light from the active layer (increase in spontaneous emission rate) could be realized.

### Example 7

FIG. 17 shows a schematic cross-sectional view of a nitride semiconductor light-emitting diode device according to Example 7 representing one example of the semiconductor light-emitting device according to the present invention. Here, the nitride semiconductor light-emitting diode device according to Example 7 has such a construction that a first n-type AlGaN layer 1702 having a thickness of 5 μm, an n-type InAlGaN intermediate layer 1703 having a thickness of 4 nm, a second lower layer 1704, a multiple quantum well active later 1705, and a second n-type AlGaN layer 1706 having a thickness of 20 nm are stacked in this order on an n-type AlGaN substrate 1701 having a thickness of 200 μm, in which a first n electrode 1707 is formed on a back surface of n-type AlGaN substrate 1701 and a second n electrode 1708 is formed on second n-type AlGaN layer 1706.

Here, second lower layer 1704 includes a p-type AlGaN layer 1704a having a thickness of 0.3 μm, a p-type AlGaN carrier blocking layer 1704b having a thickness of 10 nm, a non-doped InAlGaN layer 1704c having a thickness of 60 nm, and a non-doped InAlGaN layer 1704d having a thickness of 8 nm that are successively stacked. It is noted that non-doped InAlGaN layer 1704c and non-doped InAlGaN layer 1704d on p-type AlGaN carrier blocking layer 1704b play a role like a buffer layer for forming good multiple quantum well active later 1705 on p-type AlGaN carrier blocking layer 1704b relatively small in lattice constant, and they also play a role to prevent diffusion of Mg from p-type AlGaN carrier blocking layer 1704b to multiple quantum well active later 1705 because light emission efficiency may lower in the event that Mg diffuses into multiple quantum well active later 1705.

Multiple quantum well active later 1705 has such a stack structure that an Si-doped InAlGaN well layer having a thickness of 3 nm, an Si-doped InAlGaN barrier layer having a thickness of 4 nm, and an Si-doped InAlGaN well layer having a thickness of 3 nm are successively stacked.

First n electrode 1707 is formed on the back surface of n-type AlGaN substrate 1701, and first n electrode 1707 is formed in contact with the back surface of n-type AlGaN substrate 1701.

In addition, second n electrode 1708 is formed on a surface of second n-type AlGaN layer 1706, and second n electrode 1708 is formed in contact with the surface of second n-type AlGaN layer 1706. Here, second n electrode 1708 is formed of an Al layer (having a thickness of 300 nm). Thus, surface plasmon polariton (SPP) is produced at the surface of the Al layer in contact with second n-type AlGaN layer 1706 (an Al interface).

A drive voltage for causing the nitride semiconductor light-emitting diode device according to this Example 7 to emit light by injecting a current of 20 mA was 8 V. In this case, ultraviolet light (having a peak wavelength of approximately 270 nm) is emitted from multiple quantum well active later 1705. Then, the ultraviolet light is extracted to the outside through n-type AlGaN substrate 1701 of the nitride semiconductor light-emitting diode device according to Example 7 and a side surface of the nitride semiconductor light-emitting diode device according to Example 7. Estimating internal quantum efficiency of the nitride semiconductor light-emitting diode device according to Example 7, it was 10% or higher when a current of 20 mA was injected for driving and extremely high light emission efficiency was achieved as a light emitting diode that emits light having a wavelength of 270 nm.

This is considered as follows. In the nitride semiconductor light-emitting diode device according to Example 7, light emitted from multiple quantum well active later 1705 and surface plasmon at the Al interface of second n electrode 1708 were efficiently coupled to each other, and consequently a light emission enhancement effect for light from multiple quantum well active later 1705 (increase in spontaneous emission rate) could be realized to such an extent that nonradiative recombination does not give rise to a problem at room temperature.

It should be understood that the embodiments and the examples disclosed herein are illustrative and non-restrictive in every respect. The scope of the present invention is defined by the terms of the claims, rather than the description above, and is intended to include any modifications within the scope and meaning equivalent to the terms of the claims.

The nitride semiconductor light-emitting device according to the present invention can suitably be used, for example, for illumination applications or display applications.

The semiconductor light-emitting device according to the present invention has high light emission efficiency, and it can suitably be used, for example, for communication applications in an infrared region, for illumination applications or display applications in a visible region, and for disinfection, water purification and the like in an ultraviolet region.

1. A nitride semiconductor light-emitting device, comprising:
an n-type nitride semiconductor layer;
a nitride semiconductor layer provided on said n-type nitride semiconductor layer;
a p-type nitride semiconductor layer provided on said nitride semiconductor layer; and
an active layer provided on said p-type nitride semiconductor layer.

2. A nitride semiconductor light-emitting device, comprising:
an n-type nitride semiconductor layer;
a nitride semiconductor layer provided on said n-type nitride semiconductor layer and having a polar plane in at least a part thereof;
a p-type nitride semiconductor layer provided on said nitride semiconductor layer; and
an active layer provided on said p-type nitride semiconductor layer.

3. The nitride semiconductor light-emitting device according to claim 2, wherein
said nitride semiconductor layer contains aluminum.

4. The nitride semiconductor light-emitting device according to claim 2, wherein
said nitride semiconductor layer comprises AlₓGa₁₋ₓN (0<x≦1).

5. The nitride semiconductor light-emitting device according to claim 2, comprising a second n-type nitride semiconductor layer provided on said active layer, wherein
a first electrode in contact with said n-type nitride semiconductor layer is an anode electrode, and
a second electrode in contact with said second n-type nitride semiconductor layer is a cathode electrode.

6. The nitride semiconductor light-emitting device according to claim 2, wherein
said nitride semiconductor layer has a thickness not smaller than 0.5 nm and not greater than 30 nm.

7. The nitride semiconductor light-emitting device according to claim 2, wherein
said active layer has a well layer composed of a group III nitride semiconductor containing In, and
an In composition ratio in said well layer is not lower than 0.15 and not higher than 0.4.

8. The nitride semiconductor light-emitting device according to claim 2, wherein
said active layer has a well layer composed of a group III nitride semiconductor containing In, and
an In composition ratio in said well layer is not lower than 0.2 and not higher than 0.4.

9. A semiconductor light-emitting device, comprising:
a substrate;
a first lower layer provided on said substrate and containing an n-type semiconductor;
a second lower layer provided above said first lower layer and containing a p-type semiconductor;
an active layer provided on said second lower layer;
an upper layer provided on said active layer and containing an n-type semiconductor;
a first electrode for n-type provided in contact with said substrate or said first lower layer; and
a second electrode for n-type provided on said upper layer in contact therewith,
said upper layer having a thickness not greater than 40 nm, and
an interface of said second electrode for n-type in contact with said upper layer containing a metal of which surface plasmon can be excited by light generated from said active layer.

10. The semiconductor light-emitting device according to claim 9, wherein
said metal of which surface plasmon can be excited by light generated from said active layer includes any of Ag, Au and Al as a main component.

11. The semiconductor light-emitting device according to claim 9, wherein
said first electrode for n-type is an anode electrode and said second electrode for n-type is a cathode electrode.

12. The semiconductor light-emitting device according to claim 9, being a nitride semiconductor light-emitting device.

13. The semiconductor light-emitting device according to claim 12, further comprising an intermediate layer between said first lower layer and said second lower layer, wherein
said intermediate layer includes tensile strain attributed to difference in lattice constant between said first lower layer and said second lower layer.

14. The semiconductor light-emitting device according to claim 9, wherein
said substrate is an n-type conductive substrate and said first electrode for n-type is provided in contact with said n-type conductive substrate.
